(19) United States
(12) Patent Application Publication
(10) Pub. No.: US 2026/0334053 A1
(43) Pub. Date: Oct. 22, 2026

(54) DISPLAY PANEL AND DISPLAY DEVICE

(71) Applicant: Hefei Visionox Technology Co., Ltd., Hefei (CN)

(72) Inventors: Zhengkui DONG, Hefei (CN); Jen-Yu LEE, Hefei (CN); Lubiao SUN, Hefei (CN); Tian WANG, Hefei (CN)

(73) Assignee: Hefei Visionox Technology Co., Ltd., Hefei (CN)

(21) Appl. No.: 19/433,922

(22) Filed: Dec. 28, 2025

Related U.S. Application Data
(63) Continuation of application No. PCT/CN2025/132564, filed on Nov. 5, 2025.

(30) Foreign Application Priority Data
Apr. 16, 2025 (CN) 202510480056.X

(51) Int. Cl. H10K 59/80; H10K 59/131

(52) U.S. Cl. CPC H10K 59/8723; H10K 59/131; H10K 59/873

(57) ABSTRACT

Disclosed are a display panel and a display device. The display panel includes: an array substrate, including a plurality of scan lines; an isolation structure located on one side of the array substrate and defining a plurality of isolation openings; a plurality of light-emitting devices located on the side of the array substrate. Each light-emitting device includes a first electrode, a light-emitting structure, and a second electrode stacked in sequence, and the second electrode is electrically connected to the isolation structure. An orthographic projection of an end, close to the array substrate, of the isolation opening on the array substrate is a first projection pattern. An angle between a longest straight side of the first projection pattern of at least one type of isolation opening and an arrangement direction of the plurality of scan lines is configured to be a preset angle. Display defect may be addressed.

### CROSS-REFERENCE TO RELATED APPLICATIONS

This application is a continuation of International Application No. PCT/CN 2025/132564, filed on Nov. 5, 2025, which claims priority to Chinese Patent Application No. 202510480056X, filed on Apr. 16, 2025. The disclosures of the aforementioned applications are hereby incorporated by reference in their entireties.

### FIELD

The present application generally relates to the field of display technologies, and in particular, to a display panel and a display device.

### BACKGROUND

Organic Light Emitting Diode (OLED) display technology is regarded as the most promising new flat panel display technology for the next generation. Compared with liquid crystal display technology, OLED display technology has advantages such as low energy consumption, low cost, self-luminescence, wide viewing angle, and fast response speed.

In a traditional manufacturing process for a display panel, light-emitting pixel patterning is typically achieved through a Fine Metal Mask (FMM). FMM technology is mature and has extensive mass production experience. However, FMM technology also has issues such as limited precision, high development costs, and long development cycles. Fine Metal Mask-less technology eliminates the limitations of traditional OLED processes on display size, resolution, and other screen performance characteristics, offering advantages of high performance, full-size capability, and agile delivery. Patents CN118251982A, CN115666161A, CN116648095A, CN117062489A, CN118678742A, CN118785761A, CN115224220A, CN118678729A, CN118660529A, CN118660589A document relevant content of fine metal mask-free technology for reference.

However, current OLED display products still suffer from display defects.

### SUMMARY

In view of above, it is necessary to provide a display panel and a display device to solve aforementioned problems.

In a first aspect, embodiments of the present disclosure provide a display panel, including: an array substrate, including a plurality of scan lines arranged at intervals; an isolation structure, located on one side of the array substrate and defining a plurality of isolation openings, the plurality of isolation openings including a plurality of first isolation openings, a plurality of second isolation openings, and a plurality of third isolation openings; a plurality of light-emitting devices, located on the side of the array substrate and including a plurality of first light-emitting devices, a plurality of second light-emitting devices, and a plurality of third light-emitting devices, where the plurality of first light-emitting devices are disposed corresponding to the plurality of first isolation openings, the plurality of second light-emitting devices are disposed corresponding to the plurality of second isolation openings, and the plurality of third light-emitting devices are disposed corresponding to the plurality of third isolation openings; each of the plurality of light-emitting devices includes a first electrode, a light-emitting structure, and a second electrode stacked in sequence, and the second electrode is electrically connected to the isolation structure; an orthographic projection of an end, close to the array substrate, of an isolation opening on the array substrate is a first projection pattern; among the first isolation openings, the second isolation openings, and the third isolation openings, an angle between a longest straight side of the first projection pattern of at least one type of isolation opening and an arrangement direction of the plurality of scan lines is configured to be a preset angle, and an orthographic projection of the second electrode of the light-emitting device corresponding to the at least one type of isolation opening on the array substrate overlaps with the longest straight side of the first projection pattern.

According to the display panel provided by the embodiments of the present disclosure, the angle between the longest straight side of the first projection pattern of at least one type of isolation opening and the extension direction of the plurality of scan lines is configured to be the preset angle, which is equivalent to aligning the longest straight side of that type of isolation opening (the first, second, or third isolation opening) along a specific direction. During an evaporation process of the second electrode, a scanning direction of an evaporation source can be perpendicular to the extension direction of the longest straight side, and the orthographic projection of the second electrode overlaps with the longest straight side of the first projection pattern. In other words, this facilitates the extension of the second electrode onto a sidewall of the isolation structure corresponding to the longest straight side, thereby increasing an overlapping area between the second electrode and the isolation structure, reducing the bond impedance, and improving the display effect.

In a second aspect, the embodiments of the present disclosure provides a display panel, including: an array substrate, including a plurality of scan lines arranged at intervals; an isolation structure, located on a side of the array substrate and defining a plurality of isolation openings, the plurality of isolation openings including a plurality of first isolation openings, a plurality of second isolation openings, and a plurality of third isolation openings; a plurality of light-emitting devices, located on the side of the array substrate and including a plurality of first light-emitting devices, a plurality of second light-emitting devices, and a plurality of third light-emitting devices; where the plurality of first light-emitting devices are disposed corresponding to the plurality of first isolation openings, the plurality of second light-emitting devices are disposed corresponding to the plurality of second isolation openings, and the plurality of third light-emitting devices are disposed corresponding to the plurality of third isolation openings; each of the plurality of light-emitting devices includes a first electrode, a light-emitting structure, and a second electrode stacked in sequence, and the second electrode is electrically connected to the isolation structure; an orthographic projection of an end, close to the array substrate, of an isolation opening on the array substrate is a first projection pattern; among the first isolation openings, the second isolation openings, and the third isolation openings, a longest straight side of the first projection pattern of at least one type of isolated opening is greater than a length of the first projection pattern along a first direction; the first direction intersects with an extension direction of the longest straight side of the first projection pattern, and an orthographic projection of the second electrode of the light emitting device corresponding to the at least one isolation opening on the array substrate overlaps with the longest straight side of the first projection pattern.

In a third aspect, the embodiments of the present disclosure provides a display device, including: a display panel, where the display panel includes: an array substrate; an isolation structure, located on a side of the array substrate and defining a plurality of isolation openings, the plurality of isolation openings including a plurality of first isolation openings, a plurality of second isolation openings, and a plurality of third isolation openings; a plurality of light-emitting devices, located on the side of the array substrate and including a plurality of first light-emitting devices, a plurality of second light-emitting devices, and a plurality of third light-emitting devices, where the plurality of first light-emitting devices are disposed corresponding to the plurality of first isolation openings, the plurality of second light-emitting devices are disposed corresponding to the plurality of second isolation openings, the plurality of third light-emitting devices are disposed corresponding to the plurality of third isolation openings; the first light-emitting devices, second light-emitting devices, and third light-emitting devices respectively emitting light of different colors; each of the plurality of light-emitting devices includes a first electrode, a light-emitting structure, and a second electrode stacked in sequence, and the second electrode being electrically connected to the isolation structure; an orthographic projection of an end, close to the array substrate, of an isolation opening on the array substrate is a first projection pattern; among the first isolation openings, the second isolation openings, and the third isolation openings, and an orthographic projection of the second electrode of the light-emitting device corresponding to at least one type of isolation opening on the array substrate overlaps with a longest straight side of the first projection pattern; and a plurality of connecting fingers arranged at intervals, where an arrangement direction of the plurality of connecting fingers intersects with the longest straight side of the first projection pattern of the at least one type of isolation opening.

According to the display device provided by the embodiments of the present disclosure, the longest straight side of the first projection pattern of at least one type of isolation opening is configured to intersect with the arrangement direction of the connecting fingers, which is equivalent to extending the longest straight side of the isolation opening (the first, second, or third isolation opening) in a specific direction. During an evaporation process of the second electrode, a scanning direction of an evaporation source may be made perpendicular to the extension direction of the longest straight side, and the orthographic projection of the second electrode overlaps with the longest straight side of the first projection pattern. In other words, this facilitates the extension of the second electrode onto a sidewall of the isolation structure corresponding to the longest straight side, thereby increasing an overlapping area between the second electrode and the isolation structure, reducing the bond impedance, and improving the display effect.

### BRIEF DESCRIPTION OF THE DRAWINGS

To more clearly illustrate the embodiments or exemplary embodiments of the present disclosure, accompanying drawings used in the description of the embodiments or exemplary embodiments will be briefly introduced below. In one embodiment, the accompanying drawings in the following description are only some embodiments of the present disclosure.

FIG. 1 is a plan view of a display panel according to an embodiment of the present disclosure.

FIG. 2A is a partial cross-sectional view of some film layers of the display panel shown in FIG. 1.

FIG. 2B is another partial cross-sectional view of some film layers of the display panel shown in FIG. 1.

FIG. 3 is a plan view of an isolation structure and light-emitting devices of the display panel shown in FIG. 1.

FIG. 4 is a plan view of the isolation structure shown in FIG. 3.

FIG. 5 is a schematic diagram showing an arrangement of isolation openings in FIG. 4.

FIG. 6 is a schematic diagram of a first projection pattern of a first isolation opening in FIG. 5.

FIG. 7 is a schematic diagram of a first projection pattern of a second isolation opening in FIG. 5.

FIG. 8 is a schematic diagram of a first projection pattern of a third isolation opening in FIG. 5.

FIG. 9 is a schematic diagram of an arrangement of partial isolation openings in FIG. 5.

FIG. 10 is a schematic diagram of another arrangement of partial isolation openings in FIG. 5.

FIG. 11 is a schematic diagram of an arrangement of a second electrode of a display panel shown in FIG. 1.

FIG. 12 is a schematic diagram of an arrangement of a first electrode of a display panel shown in FIG. 1.

FIG. 13 is a schematic diagram of an arrangement of a light-emitting structure of the display panel shown in FIG. 1.

FIG. 14 is a schematic diagram of an arrangement of an encapsulation portion of the display panel shown in FIG. 1.

FIG. 15 is another partial cross-sectional view of some film layers of the display panel shown in FIG. 1.

FIG. 16 is another plan view of the isolation structure shown in FIG. 3.

FIG. 17 is yet another plan view of the isolation structure shown in FIG. 3.

FIG. 18 is a structural schematic diagram of a display device provided by an embodiment of the present disclosure.

FIG. 19 is a partial structural schematic diagram of the display device shown in FIG. 18.

### DETAILED DESCRIPTION OF THE EMBODIMENTS

Display panels manufactured using fine metal mask-free technology have a characteristic of high Pixels Per Inch (PPI) and can make sub-pixels smaller. However, after sub-pixels become smaller, there is a problem of display defects, such as color unevenness under low grayscale conditions. Through research, the inventors discovered that the cause of the aforementioned problem is: the electrical bond impedance between the sub-pixel cathode and the isolation structure is relatively large.

In view of above, embodiments of the present disclosure provide a display panel and a display device. By setting an angle between a longest straight side of a first projection pattern of at least one type of isolation opening and an extension direction of a scanning line to a preset angle, it is equivalent to making the longest straight side of this type of isolation opening (for example, a first isolation opening, a second isolation opening, or a third isolation opening) extend along a specific direction. During an evaporation process of a second electrode, a scanning direction of the evaporation source can be made perpendicular to an extension direction of the longest straight side, and an orthographic projection of the second electrode overlaps with the longest straight side of the first projection pattern. In other words, this helps the second electrode extend to a sidewall of an isolation structure corresponding to the longest straight side, thereby increasing a contact area between the second electrode and the isolation structure, reducing the contact impedance, and improving the display effect.

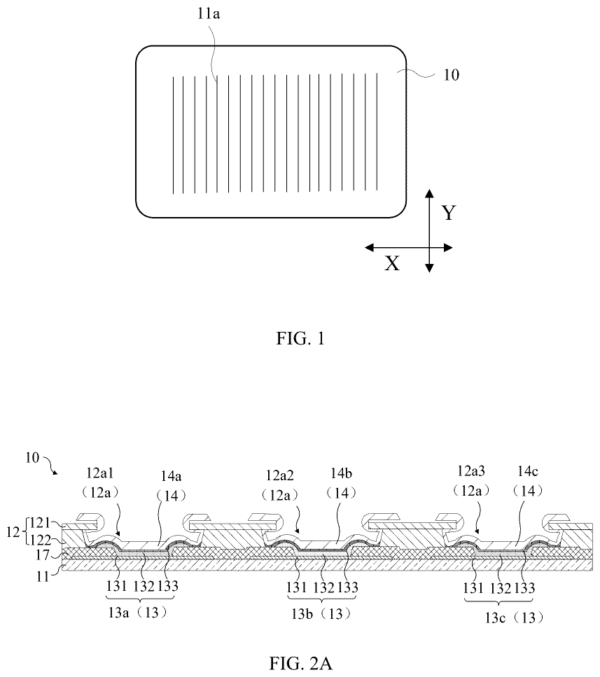

As shown in FIGS. 1 to 15, embodiments of the present disclosure provide a display panel 10. The display panel 10 may be an Organic Light Emitting Diode (OLED) display panel 10 or a Quantum Dot Light Emitting Diodes (QLED) display panel 10.

In one embodiment, the display panel 10 includes an array substrate 11, an isolation structure 12, and a plurality of light-emitting devices 13. The array substrate 11 includes a plurality of scanning lines 11a arranged at intervals. The isolation structure 12 is located on a side of the array substrate 11 and a plurality of isolation openings 12a are defined by the isolation structure 12. The plurality of isolation openings 12a include a plurality of first isolation openings 12a1, a plurality of second isolation openings 12a2, and a plurality of third isolation openings 12a3. The plurality of light-emitting devices 13 are located on a side of the array substrate 11 and the plurality of light-emitting devices 13 include a plurality of first light-emitting devices 13a, a plurality of second light-emitting devices 13b, and a plurality of third light-emitting devices 13c. The first light-emitting device 13a corresponds to the first isolation opening 12a1, the second light-emitting device 13b corresponds to the second isolation opening 12a2, and the third light-emitting device 13c corresponds to the third isolation opening 12a3. For example, the first light-emitting device 13a is arranged in one-to-one correspondence with the first isolation opening 12a1, the second light-emitting device 13b is arranged in one-to-one correspondence with the second isolation opening 12a2, and the third light-emitting device 13c is arranged in one-to-one correspondence with the third isolation opening 12a3. At least part of each first light-emitting device 13a is located within the corresponding first isolation opening 12a1, at least part of each second light-emitting device 13b is located within the corresponding second isolation opening 12a2, and at least part of each third light-emitting device 13c is located within the corresponding third isolation opening 12a3. From a planar perspective, the size and shape of the isolation opening 12a match the size and shape of the light-emitting devices 13.

The first light-emitting device 13a, the second light-emitting device 13b, and the third light-emitting device 13c are respectively used to emit light of different colors. Each light-emitting device 13 includes a first electrode 131, a light-emitting structure 132, and a second electrode 133 stacked in sequence, and the second electrode 133 is electrically connected to the isolation structure 12. The first electrode 131 may be an anode, and the second electrode 133 may be a cathode.

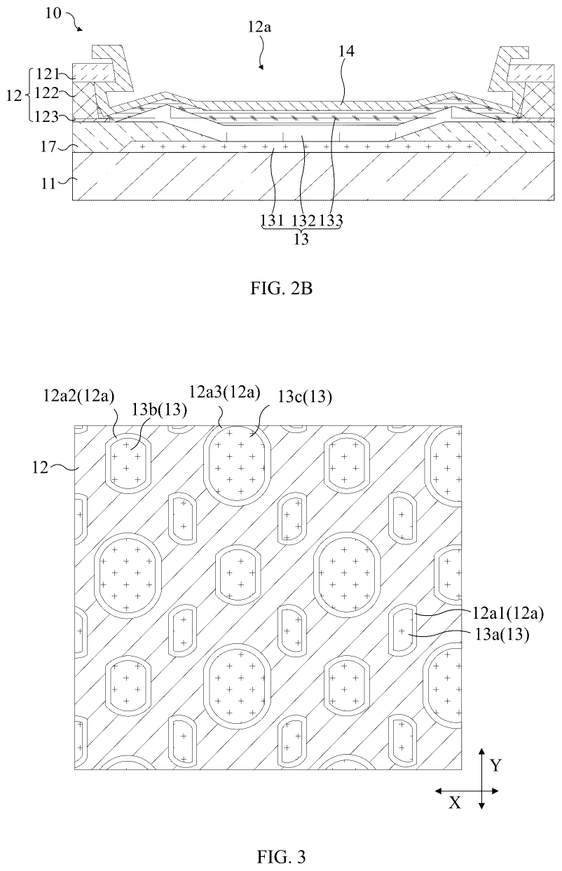

An orthographic projection of an end, close to the array substrate 11, of the isolation opening 12a on the array substrate 11 is a first projection pattern. As shown in FIG. 2A, the isolation opening 12a extends through the isolation structure 12 along a vertical direction, and the end, close to the array substrate 11, of the isolation opening 12a is a bottom end of the isolation opening 12a. In other words, the first projection pattern may also be considered as an orthographic projection of the bottom end of a sidewall, closer to the isolation opening 12a, of the isolation structure 12 on the array substrate 11. In one example, as shown in FIG. 2A, the isolation structure 12 includes an isolation body 122 and a barrier portion 121 stacked sequentially in a direction away from the array substrate 11. An orthographic projection of a bottom end of a sidewall, closer to the isolation opening 12a, of the isolation body 122 on the array substrate 11 is the first projection pattern. In one embodiment, a material of the isolation body 122 may include aluminum (Al), and a material of the barrier portion 121 may include titanium (Ti). In another example, as shown in FIG. 2B, the isolation structure 12 includes a base portion 123, an isolation body 122, and a barrier portion 121 stacked sequentially in a direction away from the array substrate 11. An orthographic projection of a bottom end of a sidewall, closer to the isolation opening 12a, of the base portion 123 on the array substrate 11 is the first projection pattern. In one embodiment, a material of the base portion 123 may include molybdenum (Mo), a material of the isolation body 122 may include aluminum (Al), and a material of the barrier portion 121 may include titanium (Ti).

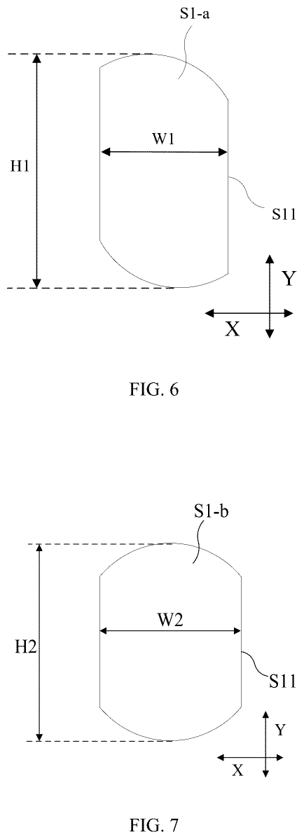

Furthermore, for at least one type of isolation opening 12a among the first isolation opening 12a1, the second isolation opening 12a2 and the third isolation opening 12a3, an angle between a longest straight side of the first projection pattern and an arrangement direction of the plurality of scan lines 11a (for example, an angle α shown in FIG. 6) is configured to be a preset angle. An orthographic projection of the second electrode 133 of the light-emitting device 13 corresponding to the at least one type of isolation opening 12a on the array substrate 11 overlaps with the longest straight side of the first projection pattern.

The ‘longest straight side’ of the first projection pattern refers to a straight side with the greatest length among all straight sides of the first projection pattern. In actual manufacturing processes, due to process variations, the longest straight side of the first projection pattern may not be an absolutely straight line. Furthermore, burrs may easily exist on the sidewall, closer to the isolation opening 12a, of the isolation structure 12 (for example, the sidewall, closer to the isolation opening, of the base portion), causing burrs to exist on the longest straight side of the first projection pattern, meaning the longest straight side is not an absolutely straight line. Therefore, the ‘straight side’ here can also be an approximately straight side.

In the embodiments of the present disclosure, the preset angle is greater than or equal to 0° and less than or equal to 90°. In one example, if the preset angle is 0°, then the longest straight side of the first projection pattern is parallel to the arrangement direction of the plurality of scanning lines 11a. In another example, if the preset angle is 90 °, then the longest straight side of the first projection pattern is perpendicular to the arrangement direction of the plurality of scanning lines 11a. In yet another example, the preset angle is 45°. In actual manufacturing processes, due to process variations, there may be some deviation between the preset angle and 0°, 90°, or 45°. Therefore, the preset angle may be an angle close to 0°, 90°, or 45°, for example, with a deviation within 0° to 5° from 0°, 90°, or 45°.

In an embodiment, the orthographic projection of the second electrode 133 of the light-emitting device 13 corresponding to at least one isolation opening 12a on the array substrate 11 overlaps with the longest straight side of this first projection pattern, and the second electrode 133 also extends to the sidewall of the isolation structure 12, thereby achieving connection between the second electrode 133 and the sidewall of the isolation structure 12.

By setting the angle between the longest straight side of the first projection pattern of at least one type of isolation opening 12a and the arrangement direction of the plurality of scanning lines 11a as a preset angle, the longest straight side of this type of isolation opening 12a (for example, the first isolation opening 12a1, the second isolation opening 12a2, or the third isolation opening 12a3) extend along a specific direction. When evaporating the second electrode 133, the scanning direction of the evaporation source may be perpendicular to the extension direction of the longest straight side, and the orthographic projection of the second electrode 133 overlaps with the longest straight side of the first projection pattern. In other words, this facilitates the extension of the second electrode 133 to the sidewall of the isolation structure 12 corresponding to the longest straight side, thereby increasing an overlapping area between the second electrode 133 and the isolation structure 12, reducing the bond impedance, and improving the display effect.

In an embodiment, the plurality of scanning lines 11a are arranged along a first direction X, and each scanning line 11a extends along a second direction Y. The longest straight side of the first projection pattern is perpendicular to the first direction X. When evaporating the second electrode 133, the evaporation source is used for scanning along the first direction X. The display panel 10 has a planar shape similar to a quadrilateral. An extension direction of a long side of the display panel 10 is the first direction X. and an extension direction of a short side of the display panel 10 is the second direction Y. Corners where the short side and long side meet can be formed as rounded corners with a predetermined curvature or as right angles. Of course, the planar shape of the display panel 10 may be formed to resemble other polygons, circles, or ellipses.

In one embodiment, in the first projection pattern of at least one type of isolation opening 12a, the longest straight side of the first projection pattern is greater than a length of the first projection pattern along the first direction X. The first direction X intersects with the extension direction of the longest straight side of the first projection pattern. In one example, as shown in FIG. 6, the first projection pattern of the first isolation opening 12a1 is a first projection pattern S1-a, and the longest straight side of the first projection pattern S1-a is a first projection edge S11. A length (that is, length H1) of the first projection edge S11 of the first projection pattern S1-a is greater than a length (that is, width W1) of the first projection pattern S1-a in the first direction X. Thus, the planar shape of the first isolation opening 12a1 is relatively “slender”. When evaporating the second electrode 133, the scanning direction of the evaporation source can be made parallel to the first direction X, and the orthographic projection of the second electrode 133 overlaps with the longest straight side of the first projection pattern. In other words, this facilitates the extension of the second electrode 133 to the sidewall of the isolation structure 12 corresponding to the longest straight side, thereby increasing an overlapping area between the second electrode 133 and the isolation structure 12, reducing the bond impedance, and improving the display effect.

In one embodiment, in the first projection pattern of at least one type of isolation opening 12a, a ratio of the longest straight side of the first projection pattern to the length of the first projection pattern along the first direction X is greater than or equal to 1.3. In the first projection pattern of at least one type of isolation opening 12a, the ratio of the longest straight side of the first projection pattern to the length of the first projection pattern along the first direction X is less than or equal to 2. In some embodiments, among the at least one type of isolation opening 12a, the ratio of the longest straight side to the length along the first direction X of the first projection pattern of the isolation opening 12a with the smallest opening area in the top view ranges from 1.3 to 2. For example, the ratio of the longest straight side of the first projection pattern to the length of the first projection pattern along the first direction X may be 1.3, 1.4, 1.5, 1.6, 1.8, 2, or between any two of these values. The above settings, on one hand, are beneficial for increasing the overlapping area between the second electrode 133 and the isolation structure 12, thereby reducing the bond impedance; on the other hand, they prevent the first isolation opening 12a1 from being too slender, causing the first light-emitting device 13a to be overly slender, which is not conducive to the arrangement of other light-emitting devices 13 and would affect the display effect.

In one embodiment, the first direction X is perpendicular to the extension direction of the longest straight side of the first projection pattern, in other words, the longest straight side of the first projection pattern extends along the second direction Y, and the second direction Y is perpendicular to the first direction X. Thus, the length of the isolation opening 12a along the first direction X corresponds to the width of the isolation opening 12a, and the aforementioned setting is equivalent to making the length of the first projection edge S11 of the first projection pattern greater than the width of the first projection pattern. This allows the planar shape of the isolation opening 12a to be relatively regular, facilitating designers to arrange it reasonably according to requirements, thereby improving the display effect.

In one embodiment, in the first projection pattern of the at least one type of isolation opening 12a, the longest straight side of the first projection pattern is greater than 10 μm. This allows for a larger overlapping area between the second electrode 133 and the isolation structure 12, which is beneficial for reducing the bond impedance.

In one embodiment, in the first projection pattern of the at least one type of isolation opening 12a, the longest straight side of the first projection pattern is greater than 16 μm. This allows for an even larger overlapping area between the second electrode 133 and the isolation structure 12, which is beneficial for further reducing the bond impedance.

In one embodiment, among the first isolation opening 12a1, the second isolation opening 12a2, and the third isolation opening 12a3, the angle between the longest straight side of the first projection pattern of the isolation opening 12a with the smallest orthographic projection area on the array substrate 11 and the arrangement direction of the plurality of scan lines 11a is configured to be a preset angle.

In the related display panel 10, the light-emitting device 13 corresponding to the isolation opening 12a with the smallest orthographic projection area has a relatively large impedance. The connection performance of the light-emitting device 13 with relatively high impedance may be improved by the embodiments of the present disclosure in one embodiment, which can significantly reduce the bond impedance of the light-emitting device 13, thereby enhancing the display effect.

In one embodiment, as shown in FIGS. 3 to 7, both the area of the orthographic projection of both the second isolation opening 12a2 and the area of the third isolation opening 12a3 on the array substrate 11 are larger than that of the first isolation opening 12a1 on the array substrate 11. An angle between the longest straight side of the first projection pattern S1-a of the first isolation opening 12a1 and the arrangement direction of the plurality of scanning lines 11a is configured to be the preset angle, and the orthographic projection of the second electrode 133 of the light-emitting device 13 corresponding to the first isolation opening 12a1 on the array substrate 11 overlaps with this longest straight side. The light-emitting areas of both the second light-emitting device 13b and the third light-emitting device 13c are larger than that of the first light-emitting device 13a. Thus, this is equivalent to improving the connection performance of the first light-emitting device 13a, which can significantly reduce the bond impedance of the first light-emitting device 13a, thereby enhancing the display effect.

In one embodiment, the first light-emitting device 13a may be a green light-emitting device 13, the second light-emitting device 13b may be a red light-emitting device 13, and the third light-emitting device 13c may be a blue light-emitting device 13.

In one of the embodiments, among the first isolation opening 12a1, the second isolation opening 12a2, and the third isolation opening 12a3, angles between the longest straight sides of the first projection patterns of at least two types of isolation openings 12a and the arrangement direction X of the plurality of scanning lines 11a is configured to be the preset angle. Thus, this is equivalent to improving the connection performance of two colors of light-emitting devices 13, which can significantly reduce the bond impedance of these two light-emitting devices 13, thereby enhancing the display effect.

In one embodiment, as shown in FIG. 7, an area of the orthographic projection of the second isolation opening 12a2 on the array substrate 11 is smaller than that of the third isolation opening 12a3 on the array substrate 11. The orthographic projection of the second electrode 133 of the light-emitting device 13 corresponding to the second isolation opening 12a2 on the array substrate 11 overlaps with the longest straight side of the first projection pattern S1-b. An angle between the longest straight side of the first projection pattern S1-b of the second isolation opening 12a2 and the arrangement direction of the plurality of scanning lines 11a is configured to be the preset angle. Understandably, the light-emitting area of the second light-emitting device 13b is smaller than that of the third light-emitting device 13c. Thus, the impedance of the two types of light-emitting devices 13 with smaller light-emitting areas are improved by the embodiments of the present disclosure in one embodiment, thereby significantly reducing the bond impedance of these two light-emitting devices 13 and enhancing the display effect.

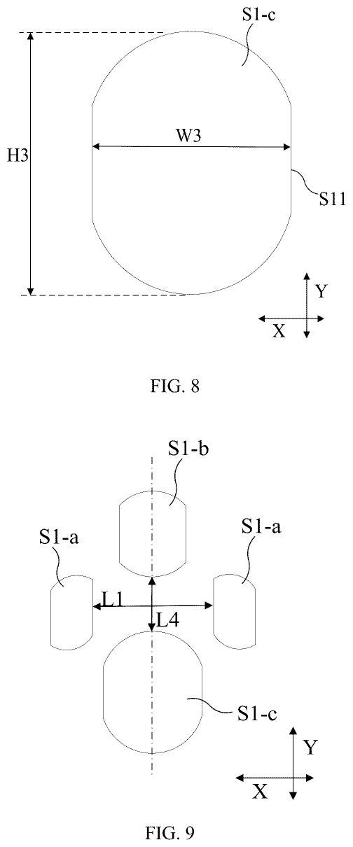

In one embodiment, among the first isolation opening 12a1, the second isolation opening 12a2, and the third isolation opening 12a3, the angle between the longest straight side of the first projection pattern of any isolation opening 12a and the arrangement direction of the plurality of scan lines 11a is configured to be the preset angle. The orthographic projection of the second electrode 133 of the light-emitting device 13 corresponding to any isolation opening 12a on the array substrate 11 overlaps with the longest straight side of this first projection pattern. As shown in FIG. 8, the angle between the longest straight side of the first projection pattern S1-c of the third isolation opening 12a3 and the arrangement direction of the plurality of scan lines 11a is configured to be a preset angle. Thus, the impedance of all light-emitting devices 13 is improved, thereby significantly reducing the bond impedance of all light-emitting devices 13 and enhancing the display effect of the display panel 10.

In one embodiment, a ratio of the longest straight side of the first projection pattern S1-b of the second isolation opening 12a2 to the longest straight side of the first projection pattern S1-a of the first isolation opening 12 a1 ranges from 0.9 to 1.1. For example, the ratio of the longest straight side of the first projection pattern S1-b of the second isolation opening 12a2 to the longest straight side of the first projection pattern S1-a of the first isolation opening 12a1 may be 0.9, 1, 1.05, or 1.1.

Furthermore, a ratio of the longest straight side of the first projection pattern S1-c of the third isolation opening 12a3 to the longest straight side of the first projection pattern S1-a of the first isolation opening 12a1 ranges from 0.5 to 2. For example, the ratio of the longest straight side of the first projection pattern S1-c of the third isolation opening 12a3 to the longest straight side of the first projection pattern S1-a of the first isolation opening 12a1 may be 0.5, 0.8, 1, 1.5, 1.8, or 2.

Factors such as light-emitting lifespan, arrangement of light-emitting devices 13, and light mixing need to be considered comprehensively for setting lengths of the longest straight sides of the first isolation opening 12a1, the second isolation opening 12a2, and the third isolation opening 12a3. The above settings not only help reduce the bond impedance of the three-color light-emitting devices 13 but also associate the lengths of the longest straight sides of the three-color light-emitting devices 13 with specific ratio relationships. During design, adjustment to the longest straight side of one color causes the other two to follow accordingly, thereby facilitating reasonable arrangement of the three-color light-emitting devices 13, ensuring good light mixing effects and longer service life.

In one embodiment, a ratio of the length of the first projection pattern S1-b of the second isolation opening 12a2 along the first direction X to the length of the first projection pattern S1-a of the first isolation opening 12a1 along the first direction X ranges from 1.5 to 2, and a ratio of the length of the first projection pattern S1-c of the third isolation opening 12a3 along the first direction X to the length of the first projection pattern S1-a of the first isolation opening 12a1 along the first direction X ranges from 2 to 3. As shown in FIGS. 6, 7 and 8, the length of the first projection pattern S1-a of the first isolation opening 12a1 along the first direction X is W1, i.e., the width of the first isolation opening 12a1 is W1; the length of the first projection pattern S1-b of the second isolation opening 12a2 along the first direction X is W2, i.e., the width of the second isolation opening 12a2 is W2; and the length of the first projection pattern S1-c of the third isolation opening 12a3 along the first direction X is W3, i.e., the width of the third isolation opening 12a3 is W3.

For example, a ratio of W2 to W1 may be 1.5, 1.8, or 2. A ratio of W3 to W1 may be 2, 2.5, or 3.

Factors such as luminescence lifetime, arrangement of light-emitting devices 13, and light mixing need to be considered comprehensively for setting widths of the first isolation opening 12a1, the second isolation opening 12a2, and the third isolation opening 12a3. The above settings allow the widths of the three-color light-emitting devices 13 to be correlated with specific ratio relationships. During design, adjustment to the width of one color causes the other two to follow accordingly, which facilitates reasonable arrangement of the three-color light-emitting devices, ensuring better light mixing effects and longer service life.

In one embodiment, a ratio of the longest straight side of the first projection pattern S1-a of the first isolation opening 12a1 to the length of the first projection pattern along the first direction X is a first value; a ratio of the longest straight side of the first projection pattern S1-b of the second isolation opening 12a2 to the length of the first projection pattern along the first direction X is a second value; and a ratio of the longest straight side of the first projection pattern S1-c of the third isolation opening 12a3 to the length of the first projection pattern along the first direction X is a third value. A ratio of the second value to the first value ranges from 0.8 to 0.9. For example, this ratio may be 0.8, 0.85, or 0.9. A ratio of the third value to the first value ranges from 0.7 to 0.85. For example, this ratio may be 0.7, 0.78, or 0.85. Here, the first value corresponds to a numerical measure of a “slenderness degree” of the shape of the first isolation opening 12a1, the second value corresponds to a numerical measure of a “slenderness degree” of the shape of the second isolation opening 12a2, and the third value corresponds to a numerical measure of a “slenderness degree” of the shape of the third isolation opening 12a3.

Factors such as light-emitting lifespan, arrangement of light-emitting devices 13, and light mixing need to be considered comprehensively for setting shapes of the first isolation opening 12a1, the second isolation opening 12a2, and the third isolation opening 12a3. The above settings can correlate the “slenderness” of the light emitting devices 13 of three colors and have a specific ratio relationship. During design, adjustment to the “slenderness degree” of one color causes the other two to follow accordingly, thereby facilitating reasonable arrangement of the three-color light-emitting devices 13, ensuring good light mixing effects and longer service life.

In one embodiment, as shown in FIG. 5, a plurality of first isolation openings 12a1 are arranged along the first direction X to form a plurality of first opening rows M1, and the plurality of first opening rows M1 are spaced apart along the second direction Y. The first direction X intersects with the extension direction of the longest straight side of the first projection pattern, and the second direction Y is parallel to the extension direction of the longest straight side of the first projection pattern. A plurality of second isolation openings 12a2 and a plurality of third isolation openings 12a3 are arranged along the first direction X to form a plurality of second opening rows M2, and the plurality of second opening rows M2 are spaced apart along the second direction Y. In the same second opening row M2, the second isolation openings 12a2 and the third isolation openings 12a3 are alternately arranged along the first direction X. Here, in the second opening row M2, the second isolation openings 12a2 and the third isolation openings 12a3 are arranged alternately in sequence.

Thus, with the above arrangement, it is beneficial to specially design the shapes of the first isolation openings 12a1, the second isolation openings 12a2, and the third isolation openings 12 a3. In other words, the first isolation openings 12a1, second isolation openings 12a2, and third isolation openings 12a3 are designed as slender types, which can not only reduce the impedance of the three-color light-emitting devices 13 but also balance service life and light mixing effects, thereby maximizing display performance.

In one embodiment, the first opening rows M1 and second opening rows M2 are alternately arranged along the second direction Y. In other words, the first opening rows M1 and second opening rows M2 are arranged alternately in sequence along the second direction Y. Thus, it is beneficial for the three-color light-emitting devices 13 to mix light, thereby improving display performance.

In one embodiment, the isolation openings 12a in the first opening rows M1 and the isolation openings 12a in the second opening rows M2 are staggered along the second direction Y. In other words, the isolation openings 12a in the first opening rows M1 and the isolation openings 12a in the second opening rows M2 are not aligned along the second direction Y. Thus, on one hand, it is beneficial to maximize the utilization of the arrangement area in the display region, thereby reasonably arranging the three-color light-emitting devices 13, and further maximizing PPI and display performance.

In one embodiment, as shown in FIG. 9, in the same first opening row M1, a distance between two adjacent first isolation openings 12a1 is a first distance L1. A ratio of the first distance L1 to the length of the first projection pattern S1-b of the second isolation opening 12a2 along the first direction X (a width W2 in FIG. 7) ranges from 1.1 to 1.5. For example, this ratio may be 1.1, 1.3, 1.4, or 1.5. A ratio of the first distance L1 to the length of the first projection shape S1-c of the third isolation opening 12a3 along the first direction X (a width W3 in FIG. 8) ranges from 1.05 to 1.3. For example, this ratio may be 1.05, 1.1, 1.2, or 1.3.

During design of the first isolation opening 12a1, the second isolation opening 12a2, and the third isolation opening 12a3, factors such as luminescence lifetime, arrangement of light-emitting devices 13, and light mixing need to be comprehensively considered. The first distance L1 determines relative positions of two adjacent first isolation openings 12a1. The above configuration means that the relative positions of the first isolation openings 12a1 is relative to the widths of the second isolation openings 12a2 and the third isolation openings 12a3, enabling a reasonable arrangement of the first, second, and third isolation openings. This ensures good light mixing effects and helps position a white light spot after light mixing at the intended location, thereby guaranteeing superior display performance.

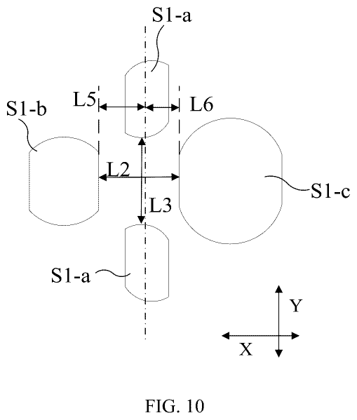

In one embodiment, as shown in FIG. 10, within the same second opening row M2, a distance between the second isolation opening 12a2 and the third isolation opening 12a3 adjacent thereto is defined as a second distance L2. A ratio of the second distance L2 to the length of the first projection shape S1-a of the first isolation opening 12a1 along the first direction X (a width W1 in FIG. 6) ranges from 1.1 to 2.2. For example, this ratio may be 1.1, 1.5, 1.8, or 2.2.

During design of the first isolation opening 12a1, second isolation opening 12a2, and third isolation opening 12a3, factors such as luminescence lifetime, arrangement of light-emitting devices 13, and light mixing need to be comprehensively considered. The second distance L2 determines relative positions of the second isolation openings 12a2 and the third isolation openings 12a3 adjacent thereto. The above configuration means that the relative position of the second isolation opening 12a2 and the third isolation opening 12a3 adjacent thereto is relative to the width of the first isolation openings 12a1, enabling a reasonable arrangement of the first, second, and third isolation openings. This ensures good light mixing effects and helps position a white light spot after light mixing at the intended location, thereby guaranteeing superior display performance.

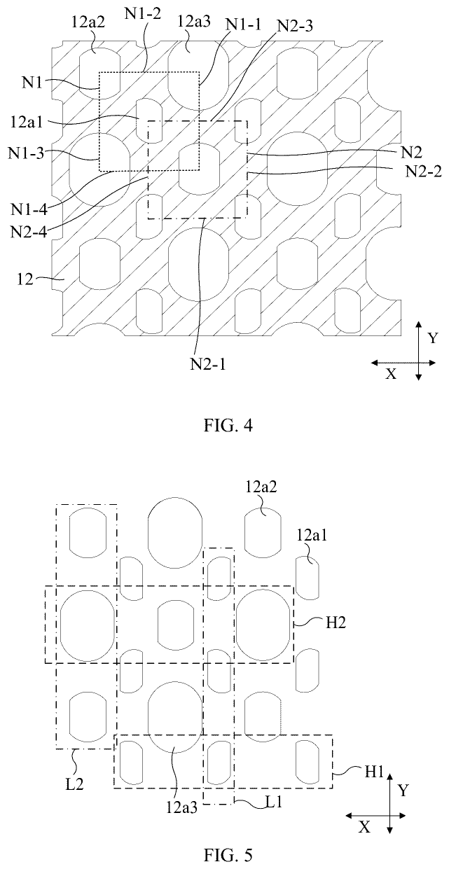

In one embodiment, as shown in FIG. 4, a first virtual polygon N1 may be formed by connecting centroids of the plurality of second isolation openings 12a2 and the plurality of third isolation openings 12a3, with at least one first isolation opening 12a1 located inside this first virtual polygon N1. Similarly, a second virtual polygon N2 may be formed by connecting centroids of the plurality of first isolation openings 12a1, with at least one second isolation opening 12a2 located inside this second virtual polygon N2. Here, the centroid of an isolation opening 12a refers to a centroid of its orthographic projection.

Thus, with the above arrangement, it is beneficial to design special shapes of the first isolation openings 12a1, the second isolation openings 12a2, and the third isolation openings 12 a3. In other words, shapes of the first isolation openings 12a1, second isolation openings 12a2, and third isolation openings 12a3 may be designed as slender types to reduce the impedance of the three-color light-emitting devices 13, as well as balance service life and light mixing effects, thereby maximizing display performance.

In one embodiment, the first virtual polygon N1 is a quadrilateral. For example, the quadrilateral can be a rectangle, trapezoid, rhombus, etc.

In one embodiment, the first virtual polygon N1 includes a first side N1-1 and a third side N1-3 parallel to each other, as well as a second side N1-2 and a fourth side N1-4 connecting the first side N1-1 and the third side N1-3.

In one embodiment, a length of the first side N1-1 is greater than a length of the third side N1-3, that is, the first virtual polygon N1 is a trapezoid. The first virtual polygon N1 may be an isosceles trapezoid.

In one embodiment, the length of the first side N1-1 equals the length of the third side N1-3, that is, the first virtual polygon N1 is a parallelogram or rectangle. The first virtual polygon N1 may be a rectangle.

In one embodiment, the second virtual polygon N2 is a quadrilateral. The second virtual polygon N2 includes a fifth side N2-1 and a seventh side N2-3 parallel to each other, as well as a sixth side N2-2 and an eighth side N2-4 connecting the fifth side N2-1 and the seventh side N2-3. For example, the quadrilateral may be a rectangle, trapezoid, rhombus, etc.

In one embodiment, the length of the fifth side N2-1 is greater than the length of the seventh side N2-3, that is, the second virtual polygon N2 is a trapezoid. The second virtual polygon N2 may be an isosceles trapezoid.

In one embodiment, the length of the fifth side N2-1 equals the length of the seventh side N2-3. That is: the second virtual polygon N2 is a parallelogram or a rectangle. In a preferred example, the second virtual polygon N2 is a rectangle.

In one embodiment, as shown in FIG. 5, a plurality of first isolation openings 12a1 are arranged along the second direction Y to form a plurality of first opening columns L1, and the plurality of first opening columns L1 are arranged at intervals along the first direction X. A plurality of second isolation openings 12a2 and a plurality of third isolation openings 12a3 are arranged along the second direction Y to form a plurality of second opening columns L2, and the plurality of second opening columns L2 are arranged at intervals along the first direction X. Within the same second opening column L2, the second isolation openings 12a2 and third isolation openings 12a3 are arranged alternately along the second direction Y. Here, in the second opening column L2, the second isolation openings 12a2 and third isolation openings 12a3 are arranged alternately in sequence.

Thus, with the above arrangement, it is beneficial to design special shapes of the first isolation openings 12a1, the second isolation openings 12a2, and the third isolation openings 12a3. In other words, the first isolation openings 12a1, the second isolation openings 12a2, and the third isolation openings 12a3 are designed as slender types to reduce the impedance of the three-color light-emitting devices 13, as well as balance service life and light mixing effects, thereby maximizing display performance.

In one embodiment, the first opening columns L1 and second opening columns L2 are arranged alternately along the first direction X. In other words, the first opening columns L1 and second opening columns L2 are arranged alternately in sequence along the first direction X. Thus, it is beneficial for the three-color light-emitting devices 13 to mix light, thereby improving display performance.

In one embodiment, the isolation openings 12a in the first opening columns L1 and those in the second opening columns L2 are staggered along the first direction X. In other words, the isolation opening 12a in the first opening row L1 and the isolation opening 12a in the second opening row L2 are not opposite to each other in the first direction X. Thus, it is beneficial to maximize the utilization of the arrangement area in the display region, thereby reasonably arranging the three-color light-emitting devices 13, and further maximizing PPI and display performance.

In one embodiment, as shown in FIG. 10, in the same first opening row L1, a distance between two adjacent first isolation openings 12a1 is a third distance L3; a ratio of the third distance L3 to the length of the first projection pattern S1-b of the second isolation opening 12a2 along the second direction Y (a length H2 in FIG. 7) ranges from 0.8 to 1.3. For example, this ratio may be 0.8, 1, 1.1, or 1.3. A ratio of the third distance to the length of the first projection pattern S1-c of the third isolation opening 12a3 along the second direction Y (a length H3 in FIG. 8) ranges from 0.6 to 1. For example, this ratio may be 0.6, 0.8, 0.9, or 1.

Factors such as luminescence lifetime, arrangement of light-emitting devices 13, and light mixing need to be comprehensively considered during a design process of the first isolation opening 12a1, second isolation opening 12a2, and third isolation opening 12a3. The third distance L3 determines the relative position of two adjacent first isolation openings 12a1. The above arrangement means that the relative position of the first isolation openings 12a1 is relative to the length of the second isolation openings 12a2 and the length of the third isolation openings 12a3, enabling a reasonable arrangement of the first isolation openings 12a1, the second isolation openings 12a2, and the third isolation openings 12a3. This ensures good light mixing effects and helps position a white light spot after light mixing at the intended location, thereby guaranteeing superior display performance.

In one embodiment, as shown in FIG. 9, in the same second opening row L2, a distance between the second isolation opening 12a2 and the third isolation opening 12a3 adjacent thereto is a fourth distance L4. A ratio of the fourth distance L4 to the length of the first projection pattern S1-a of the first isolation opening 12a1 along the second direction Y (a length H1 in FIG. 6) ranges from 0.8 to 1.2. Fr example, this ratio may be 0.8, 0.9, 1.1, or 1.2.

During design of the first isolation opening 12a1, the second isolation opening 12a2, and the third isolation opening 12a3, factors such as luminescence lifetime, arrangement of light-emitting devices 13, and light mixing need to be comprehensively considered. The fourth distance L4 determines relative positions of the second isolation opening 12a2 and the third isolation opening 12a3 adjacent thereto. The above arrangement means that the relative position of the second isolation opening 12a2 and the third isolation opening 12a3 adjacent thereto is relative to the length of the first isolation opening 12a1, enabling a reasonable arrangement of the first isolation openings 12a1, the second isolation openings 12a2, and the third isolation openings 12a3. This ensures good light mixing effects and helps position a white light spot after light mixing at the intended location, thereby guaranteeing superior display performance.

In one embodiment, as shown in FIG. 10, a distance in the first direction X between a centerline of the first isolation openings 12a1 in the first opening row L1 and a centerline of the second isolation openings 12a2 in the adjacent second opening row L2 is a fifth distance L5. A distance in the first direction X between the centerline of the first isolation openings 12a1 in the first opening row L1 and a centerline of the third isolation openings 12a3 in the adjacent second opening row L2 is a sixth distance L6. The fifth distance L5 is greater than the sixth distance L6.

The above arrangement ensures reasonable positioning of the first isolation openings 12a1, the second isolation openings 12a2, and the third isolation openings 12a3. This ensures good light mixing effects and helps position a white light spot after light mixing at the intended location, thereby guaranteeing superior display performance.

In one embodiment, the two first opening rows L1 located on both sides of the second opening row L2 along the first direction X and adjacent to the second opening row L2 are symmetrically arranged about the centerline of the second opening row L2. As shown in FIG. 9, the two first isolation openings 12a1 on both sides of the centerline of the second isolation opening 12a2 (or the third isolation opening 12a3) are symmetrically arranged.

Thus, the above arrangement ensures reasonable positioning of the first isolation openings 12a1, the second isolation openings 12a2, and the third isolation openings 12a3. This ensures good light mixing effects and helps position a white light spot after light mixing at the intended location, thereby guaranteeing superior display performance

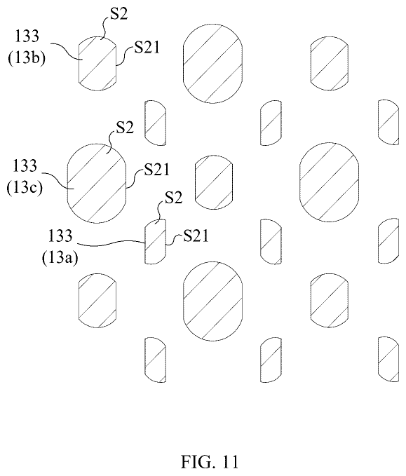

In one embodiment, as shown in FIG. 11, an orthographic projection of the second electrode 133 of the light-emitting device 13 on the array substrate 11 is a second projection pattern S2. Among the first light-emitting device 13a, the second light-emitting device 13b, and the third light-emitting device 13c, for at least one type of light-emitting device 13, an angle (an angle β shown in FIG. 11) between a longest straight side of the second projection pattern S2 and an arrangement direction of the plurality of scan lines 11a is configured to be a preset angle. In one embodiment, the second projection edge S21 of the second projection pattern S2 is the longest straight side. The outer edge of the second electrode 133 overlaps with the isolation structure 12. The second projection pattern S2 is an orthographic projection of an end, facing away from the array substrate 11, of the outer edge of the second electrode 133 (in other words, a top end of the outer edge of the second electrode 133) that is in contact with the isolation structure 12 on the array substrate 11.

Thus, a planar shape of the second electrode 133 is matched with a planar shape of the isolation opening 12a, which helps increase an overlapping area between the second electrode 133 and the isolation structure 12, thereby reducing the bond impedance of the second electrode 133.

In one embodiment, for the second projection pattern S2 of at least one type of light-emitting device 13, a ratio of the longest straight side of the second projection pattern S2 to a length of the second projection pattern S2 along the first direction X ranges from 1.3 to 2, where the first direction X intersects an extension direction of the longest straight side of the second projection pattern S2.

Thus, the planar shape of the second electrode 133 is relatively ‘slender’. During the evaporation of the second electrode 133, the scanning direction of the evaporation source may be made parallel to the first direction X, and the orthographic projection of the second electrode 133 overlaps with the longest straight side of the first projection pattern. In other words, this facilitates the extension of the second electrode 133 to the sidewall of the isolation structure 12 corresponding to the longest straight side, thereby increasing an overlapping area between the second electrode 133 and the isolation structure 12, reducing the bond impedance, and improving the display effect.

In one embodiment, for at least one type of light-emitting device 13, the longest straight side of the second projection pattern S2 is greater than 10 μm. This allows for a larger overlapping area between the second electrode 133 and the isolation structure 12, which is beneficial for reducing the bond impedance.

In one embodiment, for at least one type of light-emitting device 13, the longest straight side of the second projection pattern S2 is greater than 16 μm. This allows for an even larger overlapping area between the second electrode 133 and the isolation structure 12, which is beneficial for further reducing the bond impedance.

In one embodiment, an area of the second projection pattern S2 of the second light-emitting device 13b is greater than that of the first light-emitting device 13a and smaller than that of the third light-emitting device 13c. An angle between the longest straight side of the second projection pattern S2 of the first light-emitting device 13a and an arrangement direction of the plurality of scan lines 11a is configured to be a preset angle, and an angle between the longest straight side of the second projection pattern S2 of the second light-emitting device 13b and an arrangement direction of the plurality of scan lines 11a is configured to be a preset angle. Thus, this is equivalent to improving the connection performance of two colors of light-emitting devices 13, which can significantly reduce the bond impedance of these two light-emitting devices 13, thereby enhancing the display effect.

In one embodiment, for any light-emitting device 13 among the first light-emitting device 13a, the second light-emitting device 13b, and the third light-emitting device 13c, the angle between the longest straight side of the second projection pattern S2 and the arrangement direction of the plurality of scan lines 11a is configured to be a preset angle.

Thus, the impedance of all light-emitting devices 13 is improved, thereby significantly reducing the bond impedance of all light-emitting devices 13 and enhancing the display effect of the display panel 10.

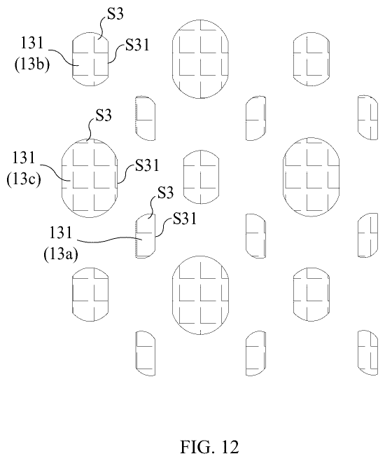

In one of the embodiments, as shown in FIG. 12, an orthographic projection of the first electrode 131 of the light-emitting device 13 on the array substrate 11 is a third projection pattern S3. Among the first light-emitting device 13a, the second light-emitting device 13b, and the third light-emitting device 13c, an angle (an angle θ shown in FIG. 12) between the longest straight side of the third projection pattern S3 of at least one light-emitting device 13 and the arrangement direction of the plurality of scan lines 11a is configured to be a preset angle. In one embodiment, a third projection edge S31 of the third projection pattern S3 is the longest straight side.

Thus, the planar shape of the first electrode 131 is matched with the planar shape of the first isolation opening 12a1, which is beneficial for improving the display effect of the display panel 10.

In one embodiment, in the third projection pattern S3 of at least one light-emitting device 13, a ratio of the longest straight side of the third projection pattern S3 to the length of the third projection pattern S3 along the first direction X ranges from 1.3 to 2, where the first direction X intersects with the extension direction of the longest straight side of the third projection pattern S3. Thus, the planar shape of the first electrode 131 is relatively slender, which is beneficial for matching the planar shape of the first electrode 131 with the planar shape of the first isolation opening 12a1.

In one embodiment, in the third projection pattern S3 of at least one light-emitting device 13, the longest straight side of the third projection pattern S3 is greater than 10 μm. Thus, it is beneficial for matching the planar shape of the first electrode 131 with the planar shape of the first isolation opening 12a1 while reducing the bond impedance.

In one embodiment, in the third projection pattern S3 of at least one light-emitting device 13, the longest straight side of the third projection pattern S3 is greater than 16 μm. Thus, it is beneficial for matching the planar shape of the first electrode 131 with the planar shape of the first isolation opening 12a1 while further reducing the bond impedance.

In one embodiment, an area of the third projection pattern S3 of the second light-emitting device 13b is larger than that of the first light-emitting device 13a and smaller than that of the third light-emitting device 13c. The angle between the longest straight side of the third projection pattern S3 of the first light-emitting device 13a and the arrangement direction of the plurality of scan lines 11a is configured to be a preset angle, and the angle between the longest straight side of the third projection pattern S3 of the second light-emitting device 13b and the arrangement direction of the plurality of scan lines 11a is configured to be a preset angle;

In one embodiment, among the first light-emitting device 13a, the second light-emitting device 13b, and the third light-emitting device 13c, an angle between the longest straight side of the third projection pattern S3 of any light-emitting device 13 and the arrangement direction of the plurality of scan lines 11a is configured to be a preset angle.

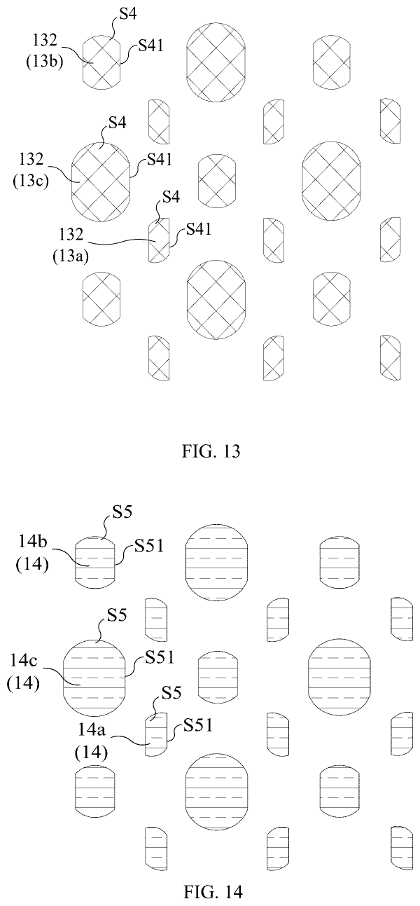

In one embodiment, as shown in FIG. 13, an orthographic projection of the light-emitting structure 132 of the light-emitting device 13 on the array substrate 11 is a fourth projection pattern S4. Among the first light-emitting device 13a, the second light-emitting device 13b, and the third light-emitting device 13c, an angle (an angle μ shown in FIG. 13) between the longest straight side of the fourth projection pattern S4 of at least one type of light-emitting device 13 and the arrangement direction of the plurality of scan lines 11a is configured to be a preset angle. In one embodiment, a fourth projection side S41 of the fourth projection pattern S4 is the longest straight side. In one example, the fourth projection pattern S4 is an orthographic projection of an outer edge contour of an overall structure of the light-emitting structure 132 (in other words, an outer edge contour of all light-emitting materials located within the isolation opening 12a) on the array substrate 11. In another example, the fourth projection pattern S4 is an orthographic projection of an effective light-emitting area of the light-emitting structure 132 on the array substrate 11, where the effective light-emitting area of the light-emitting structure 132 is determined by a pixel opening of the pixel definition layer 17; in other words, an orthographic projection of an end, close to the array substrate 11, of the pixel opening on the array substrate 11 is the fourth projection pattern S4.

Thus, the planar shape of the light-emitting structure 132 is matched with the planar shape of the first isolation opening 12a1, which helps improve the display effect of the display panel 10.

In one embodiment, in the fourth projection pattern S4 of at least one type of light-emitting device 13, a ratio of the longest straight side of the fourth projection pattern S4 to the length of the fourth projection pattern S4 along the first direction X ranges from 1.3 to 2, where the first direction X intersects with the extension direction of the longest straight side of the fourth projection pattern S4. Thus, the planar shape of the light-emitting structure 132 is relatively slender, which matches the planar shape of the first isolation opening 12a1 and helps improve the display effect of the display panel 10.

In one embodiment, in the fourth projection pattern S4 of at least one type of light-emitting device 13, the longest straight side of the fourth projection pattern S4 is greater than 10 μm. This helps match the planar shape of the light-emitting structure 132 with the planar shape of the first isolation opening 12a1, which is beneficial for improving the display effect of the display panel 10.

In one embodiment, in the fourth projection pattern S4 of at least one type of light-emitting device 13, the longest straight side of the fourth projection pattern S4 is greater than 16 μm. This helps match the planar shape of the light-emitting structure 132 with the planar shape of the first isolation opening 12a1, which is beneficial for further improving the display effect of the display panel 10.

In one embodiment, an area of the fourth projection pattern S4 of the second light-emitting device 13b is larger than that of the first light-emitting device 13a and smaller than that of the third light-emitting device 13c. An angle between the longest straight side of the fourth projection pattern S4 of the first light-emitting device 13a and an arrangement direction of the plurality of scan lines 11a is configured to be a preset angle, and an angle between the longest straight side of the fourth projection pattern S4 of the second light-emitting device 13b and the arrangement direction of the plurality of scan lines 11a is configured to be a preset angle.

In one embodiment, among the first light-emitting device 13a, the second light-emitting device 13b, and the third light-emitting device 13c, an angle between the longest straight side of the fourth projection pattern S4 of any light-emitting device 13 and the arrangement direction of the plurality of scan lines 11a is configured to be a preset angle.

In one embodiment, as shown in FIG. 14, the display panel 10 further includes a plurality of encapsulation portions 14. The plurality of encapsulation portions 14 include a plurality of first encapsulation portions 14a corresponding to the plurality of first light-emitting devices 13a, a plurality of second encapsulation portions 14b corresponding to the plurality of second light-emitting devices 13b, and a plurality of third encapsulation portions 14c corresponding to the plurality of third light-emitting devices 13c. The first encapsulation portion 14a is disposed on a side, facing away from the array substrate 11, of the corresponding first light-emitting device 13a, the second encapsulation portion 14b is disposed on the side, facing away from the array substrate 11, of the corresponding second light-emitting device 13b, and the third encapsulation portion 14c is disposed on the side, facing away from the array substrate 11, of the corresponding third light-emitting device 13c. An orthographic projection of the encapsulation portion 14 on the array substrate 11 is a fifth projection pattern S5. Among the first encapsulation portion 14a, the second encapsulation portion 14b, and the third encapsulation portion 14c, an angle (an angle γ shown in FIG. 14) between the longest straight side of the fifth projection pattern S5 of at least one type of encapsulation portion 14 and the arrangement direction of the plurality of scan lines 11a is configured to be a preset angle. In one embodiment, a fifth projection edge S51 of the fifth projection pattern S5 is the longest straight side. Here, the fifth projection pattern S5 is an orthographic projection of the effective encapsulation part of the encapsulation portion 14 on the array substrate 11, where the encapsulation portion 14 located within the isolation opening 12a is the effective part of the encapsulation portion 14. In other words, the fifth projection pattern S5 is an orthographic projection of the encapsulation portion 14 located within the isolation opening 12a on the array substrate 11.

Thus, it is equivalent to matching the planar shape of the encapsulation portion 14 with the planar shape of the isolation opening 12a, which is beneficial for ensuring the encapsulation effect.

In one embodiment, in the fifth projection pattern S5 of at least one type of light-emitting device 13, a ratio of the longest straight side of the fifth projection pattern S5 to the length of the fifth projection pattern S5 along the first direction X ranges from 1.3 to 2, where the first direction X intersects with the extension direction of the longest straight side of the fifth projection pattern S5. Thus, the planar shape of the encapsulation portion 14 is matched with the planar shape of the isolation opening 12a, which is beneficial for ensuring the encapsulation effect.

In one embodiment, in the fifth projection pattern S5 of at least one type of light-emitting device 13, the longest straight side of the fifth projection pattern S5 is greater than 10 μm. Thus, the planar shape of the encapsulation portion 14 is matched with the planar shape of the isolation opening 12a, which is beneficial for ensuring the encapsulation effect.

In one embodiment, in the fifth projection pattern S5 of at least one type of light-emitting device 13, the longest straight side of the fifth projection pattern S5 is greater than 16 μm. Thus, the planar shape of the encapsulation portion 14 is matched with the planar shape of the isolation opening 12a, which is beneficial for ensuring the encapsulation effect.

In one embodiment, an area of the fifth projection pattern S5 of the second light-emitting device 13b is larger than that of the fifth projection pattern S5 of the first light-emitting device 13a, but smaller than that of the fifth projection pattern S5 of the second light-emitting device 13. An angle between the longest straight side of the fifth projection pattern S5 of the first light-emitting device 13a and the arrangement direction of the plurality of scan lines 11a is configured to be a preset angle, and similarly for the fifth projection pattern S5 of the second light-emitting device 13b. Thus, the planar shape of the encapsulation portion 14 is matched with the planar shape of the isolation opening 12a, which is beneficial for ensuring the encapsulation effect.

In one embodiment, among the first light-emitting device 13a, the second light-emitting device 13b, and the third light-emitting device 13c, an angle between the longest straight side of any fifth projection pattern S5 of the light-emitting device 13 and the arrangement direction of the plurality of scan lines 11a is configured to be a preset angle. Thus, the planar shape of the encapsulation portion 14 is matched with the planar shape of the isolation opening 12a, which is beneficial for ensuring the encapsulation effect

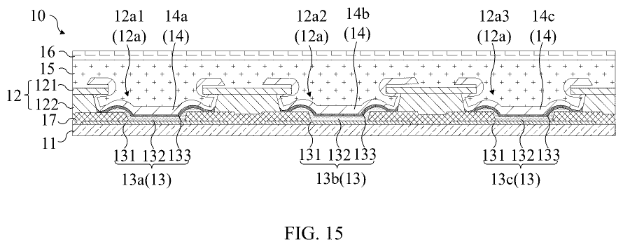

In one embodiment, as shown in FIG. 15, the display panel 10 further includes a pixel defining layer 17, which is provided with a first pixel opening (not shown), a second pixel opening (not shown), and a third pixel opening (not shown), where the first light-emitting device 13a is disposed in the first pixel opening, the second light-emitting device 13b is disposed in the second pixel opening, and the third light-emitting device 13c is disposed in the third pixel opening. A planar shape of the first pixel opening matches that of the first isolation opening 12a1, a planar shape of the second pixel opening matches that of the second isolation opening 12a2, and a planar shape of the third pixel opening matches that of the third isolation opening 12a3.

In one embodiment, the display panel 10 further includes an organic encapsulation layer 15 and an inorganic encapsulation layer 16, where the organic encapsulation layer 15 covers the isolation structure 12 and the encapsulation portion 14, and the inorganic encapsulation layer 16 covers the organic encapsulation layer 15.

In one embodiment, the second electrode 133 does not overlap with the sidewalls of the isolation opening 12a along the second direction Y. In one embodiment, the overlapping area between the second electrode 133 and the sidewalls of the isolation opening 12a along the second direction Y is smaller than the overlapping area with the sidewalls along the first direction X.

The second electrode 133 has a larger overlapping area with the sidewalls of the isolation opening 12a along the first direction X, which helps reduce bond impedance. There is no need to adjust the deposition angle during the evaporation of the second electrode 133 to achieve overlap with the sidewalls along the second direction Y, thereby reducing manufacturing costs.

In one example, the second electrode 133 does not overlap with the sidewalls of the first isolation opening 12a1 along the second direction Y. In one embodiment, the overlapping area between the second electrode 133 and the sidewalls, opposite arranged in the second direction Y, of the first isolation opening 12a1 is smaller than the overlapping area between the second electrode 133 and the sidewall, opposite arranged in the first direction X, of the first isolation opening 12a1.

In another example, the second electrode 133 does not overlap with the sidewall of the second isolation opening 12a2 facing in the second direction Y. In one embodiment, the overlapping area between the second electrode 133 and the sidewall, opposite arranged in the second direction Y, of the second isolation opening 12a2 is smaller than the overlapping area between the second electrode 133 and the sidewall, opposite arranged in the first direction X, of the second isolation opening 12a2.

In yet another example, the second electrode 133 does not overlap with the sidewall of the third isolation opening 12a3 facing in the second direction Y. In one embodiment, the overlapping area between the second electrode 133 and the sidewall, opposite arranged in the second direction Y, of the third isolation opening 12a3 facing in the second direction Y is smaller than the overlapping area between the second electrode 133 and the sidewall, opposite arranged in the first direction X, of the third isolation opening 12a3.

In one embodiment, a ratio of the longest straight side of the first projection pattern S1-b of the second isolation opening 12a2 to the longest straight side of the first projection pattern S1-a of the first isolation opening 12 a1 ranges from 0.9 to 1.1. A ratio of the longest straight side of the first projection pattern S1-c of the third isolation opening 12a3 to the longest straight side of the first projection pattern S1-a of the first isolation opening 12a1 ranges from 0.5 to 2. A ratio of the length of the first projection pattern S1-b of the second isolation opening 12a2 along the first direction X to the length of the first projection pattern S1-a of the first isolation opening 12a1 along the first direction X ranges from 1.5 to 2, and a ratio of the length of the first projection pattern S1-c of the third isolation opening 12a3 along the first direction X to the length of the first projection pattern S1-a of the first isolation opening 12a1 along the first direction X ranges from 2 to 3. The ratio of the longest straight side of the first projection pattern S1-a of the first isolation opening 12a1 to its length along the first direction X is defined as the first value; the ratio of the longest straight side of the first projection pattern S1-b of the second isolation opening 12a2 to its length along the first direction X is defined as the second value; and the ratio of the longest straight side of the first projection pattern S1-c of the third isolation opening 12a3 to its length along the first direction X is defined as the third value. The ratio of the second value to the first value ranges from 0.8 to 0.9, and the ratio of the third value to the first value ranges from 0.7 to 0.85. In the same first opening row M1, a distance between two adjacent first isolation openings 12a1 is defined as the first distance L1. A ratio of the first distance L1 to the length of the first projection pattern S1-b of the second isolation opening 12a2 along the first direction X (a width W2 in FIG. 7) ranges from 1.1 to 1.5. For example, this ratio may be 1.1, 1.3, 1.4, or 1.5. A ratio of the first distance L1 to the length of the first projection shape S1-c of the third isolation opening 12a3 along the first direction X (a width W3 in FIG. 8) ranges from 1.05 to 1.3. For example, this ratio may be 1.05, 1.1, 1.2, or 1.3. In the same second opening row M2, a distance between adjacent second isolation openings 12a2 and third isolation openings 12a3 is the second distance L2. A ratio of the second distance L2 to the length of the first projection shape S1-a of the first isolation opening 12a1 along the first direction X (a width W1 in FIG. 6) ranges from 1.1 to 2.2. For example, this ratio may be 1.1, 1.5, 1.8, or 2.2. In the same first opening column L1. A distance between two adjacent first isolation openings 12a1 is the third distance L3. A ratio of the third distance L3 to the length of the first projection pattern S1-b of the second isolation opening 12a2 along the second direction Y (a length H2 in FIG. 7) ranges from 0.8 to 1.3. For example, this ratio may be 0.8, 1, 1.1, or 1.3. A ratio of the third distance to the length of the first projection pattern S1-c of the third isolation opening 12a3 along the second direction Y (a length H3 in FIG. 8) ranges from 0.6 to 1. For example, the ratio may be 0.6, 0.8, 0.9, or 1. In the same second opening column L2, a distance between adjacent second isolation openings 12a2 and third isolation openings 12a3 is a fourth distance L4. A ratio of the fourth distance L4 to the length of the first projection pattern S1-a of the first isolation opening 12a1 along the second direction Y (a length H1 in FIG. 6) ranges from 0.8 to 1.2. For example, the ratio may be 0.8, 0.9, 1.1, or 1.2.

Thus, during design of the first isolation openings 12a1, second isolation openings 12a2, and third isolation openings 12a3, factors such as luminous lifetime, arrangement of light-emitting devices 13, and light mixing may be comprehensively considered, enabling an arrangement of the first isolation openings 12a1, the second isolation openings 12a2, and the third isolation openings 12a3. This ensures good light mixing effects and helps position a white light spot after light mixing at the intended location, thereby guaranteeing superior display performance.

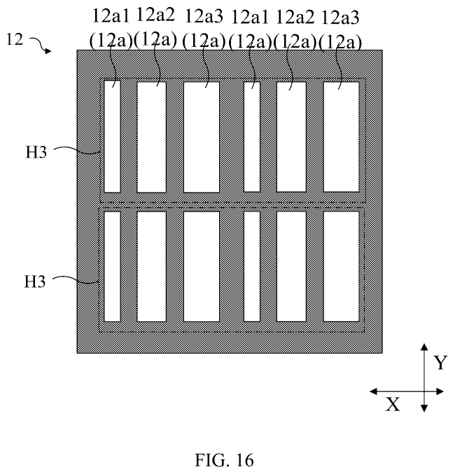

In one embodiment, as shown in FIG. 16, a plurality of first isolation openings 12a1, a plurality of second isolation openings 12a2, and a plurality of third isolation openings 12a3 are arranged along the first direction X to form a plurality of third opening rows M3, and the plurality of third opening rows M3 are sequentially arranged along the second direction Y. In the third opening row M3, the first isolation openings 12a1, the second isolation openings 12a2, and the third isolation openings 12a3 are alternately arranged in sequence. The first direction X intersects with an extension direction of the longest straight side of the first projection pattern; and the second direction Y is parallel to the extension direction of the longest straight side of the first projection pattern.

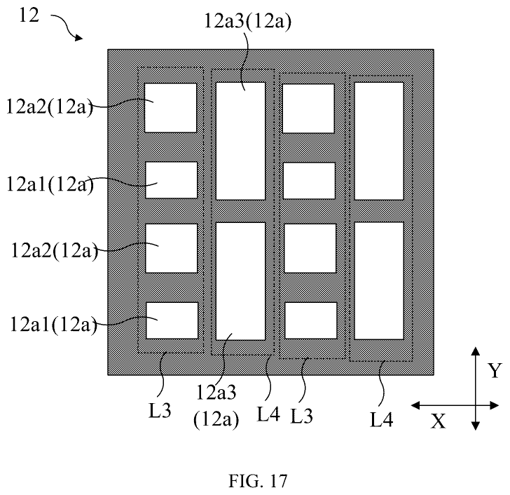

In one embodiment, as shown in FIG. 17, a plurality of first isolation openings 12a1 and a plurality of second isolation openings 12a2 are arranged along the second direction Y to form a plurality of third opening columns L3, where the first isolation openings 12a1 and second isolation openings 12a2 are alternately arranged in sequence. A plurality of third isolation openings 12a3 are arranged along the second direction Y to form a plurality of fourth opening columns L4. The third opening columns L3 and fourth opening columns L4 are alternately arranged along the first direction X. The first direction X intersects with the extension direction of the longest straight side of the first projection pattern. and the second direction Y is parallel to the extension direction of the longest straight side of the first projection pattern.

In one embodiment, the display panel 10 includes an array substrate 11, an isolation structure 12, and a plurality of light-emitting devices 13. The array substrate 11 includes a plurality of scan lines 11a. The isolation structure 12 is located on a side of the array substrate 11, where a plurality of isolation openings 12a are defined by the isolation structure 12. The plurality of isolation openings 12a include a plurality of first isolation openings 12a1, a plurality of second isolation openings 12a2, and a plurality of third isolation openings 12a3. The plurality of first isolation openings 12a1 are arranged along a first direction X to form a plurality of first opening rows M1, and the plurality of first opening rows M1 are spaced apart along a second direction Y. The plurality of second isolation openings 12a2 and the plurality of third isolation openings 12a3 are arranged along the first direction X to form a plurality of second opening rows M2, and the plurality of second opening rows M2 are spaced apart along the second direction Y. In the same second opening row M2, the second isolation openings 12a2 and third isolation openings 12a3 are alternately arranged along the first direction X. The first opening rows M1 and second opening rows M2 are alternately arranged along the second direction Y. A first virtual polygon N1 is formed by connecting centroids of the plurality of second isolation openings 12a2 and the plurality of third isolation openings 12a3, and at least one first isolation opening 12a1 is located within the first virtual polygon N1. A second virtual polygon N2 is formed by connecting centroids of the plurality of first isolation openings 12al, and at least one second isolation opening 12a2 is located within the second virtual polygon N2. The plurality of light-emitting devices 13 are located on a side of the array substrate 11 and the plurality of light-emitting devices 13 include a plurality of first light-emitting devices 13a, a plurality of second light-emitting devices 13b, and a plurality of third light-emitting devices 13c. The first light-emitting devices 13a are disposed in the first isolation openings 12a1, the second light-emitting devices 13b are disposed in the second isolation openings 12a2, and the third light-emitting devices 13c are disposed in the third isolation openings 12a3. The first light-emitting devices 13a, the second light-emitting devices 13b, and the third light-emitting devices 13c are respectively used to emit light of different colors. Each light-emitting device 13 includes a first electrode 131, a light-emitting structure 132, and a second electrode 133 stacked in sequence, and the second electrode 133 is electrically connected to the isolation structure 12.

Furthermore, an orthographic projection of an end, close to the array substrate 11, of the isolation opening 12a onto the array substrate 11 is a first projection shape. Among the first isolation openings 12a1, the second isolation openings 12a2, and the third isolation openings 12a3, for at least one type of isolation opening 12a, an angle between a longest straight side of its first projection shape and an arrangement direction of the plurality of scan lines 11a is configured to be a preset angle, and an orthographic projection of the second electrode 133 of the corresponding light-emitting device 13 onto the array substrate 11 overlaps with the longest straight side of this first projection shape. The first direction X intersects an extension direction of the longest straight side, and the second direction Y is parallel to the extension direction of the longest straight side.

Thus, it is equivalent to making the longest straight side of this type of isolation opening 12a (first isolation opening 12a1, second isolation opening 12a2, or third isolation opening 12 a3) extend along a specific direction. During evaporation of the second electrode 133, a scanning direction of the evaporation source may be perpendicular to the extension direction of the longest straight side, and the orthographic projection of the second electrode 133 overlaps with the longest straight side of the first projection shape. In other words, this facilitates the extension of the second electrode 133 to the sidewall of the isolation structure 12 corresponding to the longest straight side, thereby increasing the contact area between the second electrode 133 and the isolation structure 12, reducing the bond impedance, and improving the display effect.

An embodiment of the present disclosure further provides a display panel 10, including an array substrate 11, an isolation structure 12, and a plurality of light-emitting devices. The isolation structure 12 is located on a side of the array substrate 11 and defines a plurality of isolation openings 12a. The plurality of isolation openings 12a include a plurality of first isolation openings 12a1, a plurality of second isolation openings 12a2, and a plurality of third isolation openings 12a3. The plurality of light-emitting devices 13 are located on the side of the array substrate 11 and include a plurality of first light-emitting devices 13a, a plurality of second light-emitting devices 13b, and a plurality of third light-emitting devices 13c. The plurality of first light-emitting devices 13a are disposed corresponding to the plurality of first isolation openings 12a1, the plurality of second light-emitting devices 13b are disposed corresponding to the plurality of second isolation openings 12a2, and the plurality of third light-emitting devices 13c are disposed corresponding to the plurality of third isolation openings 12a3. Each of the plurality of light-emitting devices 13 includes a first electrode 131, a light-emitting structure 132, and a second electrode 133 stacked in sequence, and the second electrode 1333 is electrically connected to the isolation structure 12. An orthographic projection of an end, close to the array substrate 11, of an isolation opening 12a on the array substrate 11 is a first projection pattern. Among the first isolation openings 12a1, the second isolation openings 12a2, and the third isolation openings 12a3, a longest straight side (for example, a first projection edge S11 of the first projection pattern S1-a shown in FIG. 6) of the first projection pattern of at least one type of isolated opening 12a is greater than a length (for example, a width W1 shown in FIG. 6) of the first projection pattern along a first direction X. The first direction X intersects with an extension direction of the longest straight side of the first projection pattern, and an orthographic projection of the second electrode 133 of the light emitting device 13 corresponding to the at least one isolation opening 12a on the array substrate 11 overlaps with the longest straight side of the first projection pattern.

Thus, a planar shape of the isolation opening 12a is relatively “slender”. When evaporating the second electrode 133, a scanning direction of an evaporation source can be made parallel to the first direction X, and the orthographic projection of the second electrode 133 overlaps with the longest straight side of the first projection pattern. In other words, it is conducive to extending the second electrode 133 to the side wall of the isolation structure 12 corresponding to the longest straight side, thereby increasing an overlapping area between the second electrode 133 and the isolation structure 12, reducing the bond impedance, and improving the display effect.

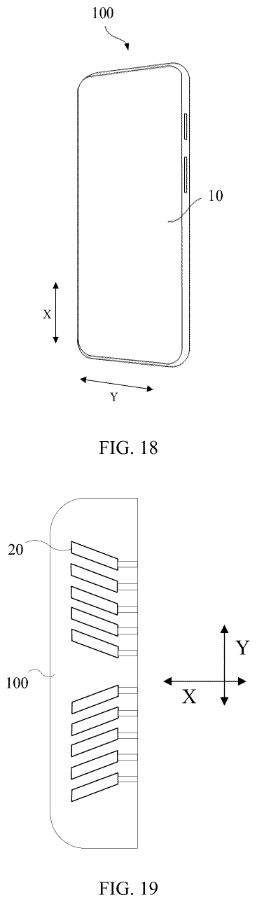

Based on the same inventive concept, as shown in FIGS. 18 and 19, the present embodiment provides a display device 100, including a display panel 10 and a plurality of connecting fingers 20 arranged at intervals. The display panel 10 includes an array substrate 11, an isolation structure 12, and a plurality of light emitting devices 13. The isolation structure 12 is located on a side of the array substrate 11 and a plurality of isolation openings 12a are defined by the isolation structure 12. The plurality of isolation openings 12a include a plurality of first isolation openings 12a1, a plurality of second isolation openings 12a2, and a plurality of third isolation openings 12a3. The plurality of light emitting devices 13 are located on a side of the array substrate 11 and include a plurality of first light emitting devices 13a, a plurality of second light emitting devices 13b, and a plurality of third light emitting devices 13c. The first light emitting device 13a corresponds to the first isolation opening 12a1, the second light emitting device 13b corresponds to the second isolation opening 12a2, and the third light emitting device 13c corresponds to the third isolation opening 12a3. The first light emitting device 13a, the second light emitting device 13b, and the third light emitting device 13c are respectively used to emit light of different colors. Each light-emitting device 13 includes a first electrode 131, a light-emitting structure 132, and a second electrode 133 arranged in a stacked manner, and the second electrode 133 electrically connected to the isolation structure 12. An orthographic projection of an end, close to the array substrate 11, of the isolation opening 12a onto the array substrate 11 is a first projection shape. Among the first isolation openings 12a1, the second isolation openings 12a2, and the third isolation openings 12a3, an orthographic projection of a second electrode corresponding to at least one type of isolation opening 12a onto the array substrate 11 overlaps with the longest straight side of this first projection shape. An arrangement direction of the plurality of connecting fingers 20 intersects with the longest straight side of the first projection pattern of at least one isolation opening 12a.

By intersecting the arrangement direction of the plurality of connecting fingers 20 with the longest straight side of the first projection pattern, it is equivalent to extending the longest straight side of the isolation opening 12a (for example, the first isolation opening 12a1, the second isolation opening 12a2, or the third isolation opening 12a3) in a specific direction. During evaporation of the second electrode 133, a scanning direction of the evaporation source may be made perpendicular to an extension direction of the longest straight side, and the orthographic projection of the second electrode 133 overlaps with the longest straight side of the first projection pattern. In other words, it is beneficial to extend the second electrode 133 to the side wall of the isolation structure 12 corresponding to the longest straight side, thereby increasing an overlapping area between the second electrode 133 and the isolation structure 12, thereby reducing bond impedance and improving the display effect.

The connecting finger 20 may be set on a flexible circuit board of the display device 100.

The arrangement direction of the plurality of connecting fingers 20 intersects and is not perpendicular to the longest straight side of the first projection pattern of at least one isolation opening 12a.

The display device 100 may be a portable electronic device such as a mobile phone, smartphone, tablet personal computer (PC), mobile communication terminal, electronic notebook, e-book, portable multimedia player (PMP), navigation device, or ultra-mobile PC (UMPC). In an embodiment, for example, the display device 100 may be a display unit of a television, laptop computer, monitor, billboard, or Internet of Things (IoT) device. In an embodiment, for example, the display device 100 may be a wearable device such as a smartwatch, watch phone, glasses-type display, or head-mounted display (HMD).

The display device 10 may be formed with a planar shape similar to a quadrilateral. In an embodiment, for example, the display device 10 may have a planar shape similar to a quadrilateral with short sides in the second direction Y and long sides in the first direction X. In one embodiment, the display device 10 may have a planar shape similar to a quadrilateral with long sides in the second direction Y and short sides in the first direction X that intersects with the second direction Y. The corners where the short sides and long sides meet may be formed as rounded with a predetermined curvature or as right angles. In an embodiment, the planar shape of the display device 10 is not limited to a quadrilateral and may be formed similar to other polygons, circles, or ovals.

When the display device 10 is a mobile phone, the isolation openings 12a may adopt the arrangement shown in FIGS. 3 and 4. When the display device 10 is a medium-sized tablet, laptop computer, or automotive display, the isolation openings 12a may adopt the arrangement shown in FIG. 16. When the display device 10 is a wearable device, the isolation openings 12a can adopt the arrangement shown in FIG. 17.

The technical features of the above embodiments can be combined arbitrarily. For the sake of concise description, not all possible combinations of the technical features in the above embodiments have been described. However, as long as there is no contradiction in the combination of these technical features, they should be considered within the scope recorded in this specification.

What is claimed is:

1. A display panel, comprising:
an array substrate, comprising a plurality of scan lines arranged at intervals;
an isolation structure, located on a side of the array substrate and defining a plurality of isolation openings, the plurality of isolation openings comprising a plurality of first isolation openings, a plurality of second isolation openings, and a plurality of third isolation openings;
a plurality of light-emitting devices, located on the side of the array substrate and comprising a plurality of first light-emitting devices, a plurality of second light-emitting devices, and a plurality of third light-emitting devices;
wherein the plurality of first light-emitting devices are disposed corresponding to the plurality of first isolation openings, the plurality of second light-emitting devices are disposed corresponding to the plurality of second isolation openings, and the plurality of third light-emitting devices are disposed corresponding to the plurality of third isolation openings; each of the plurality of light-emitting devices comprises a first electrode, a light-emitting structure, and a second electrode stacked in sequence, and the second electrode is electrically connected to the isolation structure; and
an orthographic projection of an end, close to the array substrate, of an isolation opening on the array substrate is a first projection pattern; among the first isolation openings, the second isolation openings, and the third isolation openings, an angle between a longest straight side of the first projection pattern of at least one type of isolation opening and an arrangement direction of the plurality of scan lines is configured to be a preset angle, and an orthographic projection of the second electrode of the light-emitting device corresponding to the at least one type of isolation opening on the array substrate overlaps with the longest straight side of the first projection pattern.

2. The display panel according to claim 1, wherein in the first projection pattern of the at least one type of isolation opening, the longest straight side of the first projection pattern is greater than a length of the first projection pattern along a first direction, and the first direction intersects an extension direction of the longest straight side of the first projection pattern.

3. The display panel according to claim 1, wherein in the first projection pattern of the at least one type of isolation opening, a ratio of the longest straight side of the first projection pattern to a length of the first projection pattern along a first direction is greater than 1.3.

4. The display panel according to claim 1, wherein in the at least one type of isolation opening, a ratio of the longest straight side of the first projection pattern of an isolation opening with the smallest area to a length of the first projection pattern along a first direction ranges from 1.3 to 2; and
the first direction is perpendicular to an extension direction of the longest straight side of the first projection pattern.

5. The display panel according to claim 1, wherein in the first projection pattern of the at least one type of isolation opening, the longest straight side of the first projection pattern is greater than 10 μm.

6. The display panel according to claim 1, wherein among the first isolation openings, the second isolation openings, and the third isolation openings, an angle between the longest straight side of the first projection pattern of an isolation opening with the smallest orthographic projection area on the array substrate and the arrangement direction of the plurality of scan lines is configured to be the preset angle;
an orthographic projection area of the second isolation opening on the array substrate and an orthographic projection area of the third isolation opening on the array substrate are both greater than an orthographic projection area of the first isolation opening on the array substrate; an angle between the longest straight side of the first projection pattern of the first isolation opening and the arrangement direction of the plurality of scan lines is configured to be the preset angle; and the orthographic projection of the second electrode of the light-emitting device corresponding to the first isolation opening on the array substrate overlaps with the longest straight side of the first projection pattern.

7. The display panel according to claim 6, wherein among the first isolation opening, the second isolation openings, and the third isolation openings, an angle between the longest straight side of the first projection pattern of at least two types of isolation openings and the arrangement direction of the plurality of scan lines is configured to be the preset angle.

8. The display panel according to claim 6, wherein the orthographic projection area of the second isolation opening on the array substrate is smaller than the orthographic projection area of the third isolation opening on the array substrate; the orthographic projection of the second electrode of the light-emitting device corresponding to the second isolation opening on the array substrate overlaps with the longest straight side of the first projection pattern; and an angle between the longest straight side of the first projection pattern of the second isolation opening and the arrangement direction of the plurality of scan lines is configured to be the preset angle; or
among the first isolation openings, the second isolation openings, and the third isolation openings, an angle between the longest straight side of the first projection pattern of each isolation opening and the arrangement direction of the plurality of scan lines is configured to be the preset angle, and the orthographic projection of the second electrode of the light-emitting device corresponding to each isolation opening on the array substrate overlaps with the longest straight side of the first projection pattern.

9. The display panel according to claim 6, wherein a ratio of the longest straight side of the first projection pattern of the second isolation opening to the longest straight side of the first projection pattern of the first isolation opening ranges from 0.9 to 1.1; a ratio of a longest straight side of the first projection pattern of the third isolation opening to the longest straight side of the first projection pattern of the first isolation opening ranges from 0.5 to 2.

10. The display panel according to claim 6, wherein a ratio of a length of the first projection pattern of the second isolation opening along a first direction to a length of the first projection pattern of the first isolation opening along the first direction ranges from 1.5 to 2; and a ratio of a length of the first projection pattern of the third isolation opening along the first direction to the length of the first projection pattern of the first isolation opening along the first direction ranges from 2 to 3.

11. The display panel according to claim 6, wherein a ratio of the longest straight side of the first projection pattern of the first isolation opening to a length of the first projection pattern of the first isolation opening along a first direction is a first value, a ratio of the longest straight side of the first projection pattern of the second isolation opening to a length of the first projection pattern of the second isolation opening along the first direction is a second value, and a ratio of the longest straight side of the first projection pattern of the third isolation opening to a length of the first projection pattern of the third isolation opening along the first direction is a third value; and
a ratio of the second value to the first value ranges from 0.8 to 0.9, and a ratio of the third value to the first value ranges from 0.7 to 0.85.

12. The display panel according to claim 1, wherein the plurality of first isolation openings are arranged along a first direction to form a plurality of first opening rows, the plurality of first opening rows are arranged at intervals along a second direction, the first direction intersects an extension direction of the longest straight side of the first projection pattern, and the second direction is parallel to the extension direction of the longest straight side of the first projection pattern;
the plurality of second isolation openings and the plurality of third isolation openings are arranged along the first direction to form a plurality of second opening rows, the plurality of second opening rows are arranged at intervals along the second direction; and in a same second opening row, the second isolation openings and the third isolation openings are alternately arranged along the first direction;
the first opening rows and the second opening rows are alternately arranged along the second direction; or
the isolation openings in the first opening rows and the isolation openings in the second opening rows are staggered along the second direction.

13. The display panel according to claim 12, wherein in a same first opening row, a distance between two adjacent first isolation openings is a first distance; and
a ratio of the first distance to a length of the first projection pattern of the second isolation opening along the first direction ranges from 1.1 to 1.5, and a ratio of the first distance to a length of the first projection pattern of the third isolation opening along the first direction ranges from 1.05 to 1.3.

14. The display panel according to claim 12, wherein in a same second opening row, a distance between adjacent second isolation opening and third isolation opening is a second distance; and
a ratio of the second distance to a length of the first projection pattern of the first isolation opening along the first direction ranges from 1.1 to 2.2.

15. The display panel according to claim 12, wherein at least one of the first isolation openings is located within a first virtual polygon defined by connection of centroids of the plurality of second isolation openings and the plurality of third isolation openings, and at least one of the second isolation openings is located within a second virtual polygon defined by connection of centroids of the plurality of first isolation openings.

16. The display panel according to claim 15, wherein the first virtual polygon is a quadrilateral;
the first virtual polygon comprises a first side and a third side parallel to each other, and a second side and a fourth side connecting the first side and the third side;
a length of the first side is greater than a length of the third side, or the length of the first side is equal to the length of the third side;
the second virtual polygon is a quadrilateral; the second virtual polygon comprises a fifth side and a seventh side parallel to each other, and a sixth side and an eighth side connecting the fifth side and the seventh side; and
a length of the fifth side is greater than a length of the seventh side.

17. The display panel according to claim 1, wherein the plurality of first isolation openings are arranged along a second direction to form a plurality of first opening columns, and the plurality of first opening columns are arranged at intervals along a first direction, the first direction intersects an extension direction of the longest straight side of the first projection pattern, and the second direction is parallel to the extension direction of the longest straight side of the first projection pattern;
the plurality of second isolation openings and the plurality of third isolation openings are arranged along the second direction to form a plurality of second opening columns, and the plurality of second opening columns are arranged at intervals along the first direction; in a same second opening column, the second isolation openings and the third isolation openings are alternately arranged along the second direction.

18. The display panel according to claim 17, wherein the first opening columns and the second opening columns are alternately arranged along the first direction; and
the isolation openings in the first opening columns and the isolation openings in the second opening columns are staggered along the first direction.

19. The display panel according to claim 17, wherein in a same first opening column, a distance between two adjacent first isolation openings is a third distance; and
a ratio of the third distance to a length of the first projection pattern of the second isolation opening along the second direction ranges from 0.8 to 1.3, and a ratio of the third distance to a length of the first projection pattern of the third isolation opening along the second direction ranges from 0.6 to 1.

20. The display panel according to claim 17, wherein in the same second opening column, a distance between adjacent second isolation opening and third isolation opening is a fourth distance; and
a ratio of the fourth distance to a length of the first projection pattern of the first isolation opening along the second direction ranges from 0.8 to 1.2.

21. The display panel according to claim 17, wherein a distance between a center line of the plurality of first isolation openings in a first opening column and a second isolation opening in an adjacent second opening column along the first direction is a fifth distance, a distance between the center line of the plurality of first isolation openings in the first opening column and a third isolation opening in the adjacent second opening column along the first direction is a sixth distance, and the fifth distance is greater than the sixth distance; and
two first opening columns located on both sides of the second opening column along the first direction and adjacent to the second opening column are symmetrically arranged about a center line of the second opening column.

22. The display panel according to claim 1, wherein the plurality of first isolation openings, the plurality of second isolation openings, and the plurality of third isolation openings are arranged along a first direction to form a plurality of third opening rows, and the plurality of third opening rows are sequentially arranged along a second direction; in a third opening row, the first isolation openings, the second isolation openings, and the third isolation openings are alternately arranged in sequence; and
the first direction intersects an extension direction of the longest straight side of the first projection pattern, and the second direction is parallel to the extension direction of the longest straight side of the first projection pattern.

23. The display panel according to claim 1, wherein the plurality of first isolation openings and the plurality of second isolation openings are arranged along a second direction to form a plurality of third opening columns, and in a third opening column, the first isolation openings and the second isolation openings are alternately arranged in sequence;
the plurality of third isolation openings are arranged along the second direction to form a plurality of fourth opening columns, and the plurality of third opening columns and the plurality of fourth opening columns are alternately arranged along a first direction; and
the first direction intersects an extension direction of the longest straight side of the first projection pattern, and the second direction is parallel to the extension direction of the longest straight side of the first projection pattern.

24. The display panel according to claim 1, wherein an orthographic projection of the second electrode of the light-emitting device on the array substrate is a second projection pattern; among the first light-emitting devices, the second light-emitting devices, and the third light-emitting devices, an angle between a longest straight side of the second projection pattern of at least one type of light-emitting device and the arrangement direction of the plurality of scan lines is configured to be the preset angle;
in the second projection pattern of the at least one type of light-emitting device, a ratio of the longest straight side of the second projection pattern to a length of the second projection pattern along a first direction ranges from 1.3 to 2, and the first direction intersects an extension direction of the longest straight side of the second projection pattern; and
in the second projection pattern of the at least one type of light-emitting device, the longest straight side of the second projection pattern is greater than 10 μm.

25. The display panel according to claim 24, wherein an area of the second projection pattern of a second light-emitting device is greater than an area of the second projection pattern of a first light-emitting device, and less than an area of the second projection pattern of a third light-emitting device;
an angle between the longest straight side of the second projection pattern of the first light-emitting device and the arrangement direction of the plurality of scan lines is configured to be the preset angle, and an angle between the longest straight side of the second projection pattern of the second light-emitting device and the arrangement direction of the plurality of scan lines is configured to be the preset angle; or
for each light-emitting device among the first light-emitting devices, the second light-emitting devices, and the third light-emitting devices, the angle between the longest straight side of the second projection pattern and the arrangement direction of the plurality of scan lines is configured to be the preset angle.

26. The display panel according to claim 1, wherein an orthographic projection of the first electrode of the light-emitting device on the array substrate is a third projection pattern; among the first light-emitting device, the second light-emitting device, and the third light-emitting device, an angle between a longest straight side of the third projection pattern of at least one type of light-emitting device and the arrangement direction of the plurality of scan lines is configured to be the preset angle;
in the third projection pattern of the at least one type of light-emitting device, a ratio of the longest straight side of the third projection pattern to a length of the third projection pattern along a first direction ranges from 1.3 to 2, and the first direction intersects with an extension direction of the longest straight side of the third projection pattern;
in the third projection pattern of the at least one type of light-emitting device, the longest straight side of the third projection pattern is greater than 10 μm;
an area of the third projection pattern of the second light-emitting device is greater than an area of the third projection pattern of the first light-emitting device, and less than an area of the third projection pattern of the third light-emitting device; and
an angle between the longest straight side of the third projection pattern of the first light-emitting device and the arrangement direction of the plurality of scan lines is configured to be the preset angle, and an angle between the longest straight side of the third projection pattern of the second light-emitting device and the arrangement direction of the plurality of scan lines is configured to be the preset angle; or for each light-emitting device among the first light-emitting devices, the second light-emitting devices, and the third light-emitting devices, the angle between the longest straight side of the third projection pattern of each light-emitting device and the arrangement direction of the plurality of scan lines is configured to be the preset angle.

27. The display panel according to claim 1, wherein an orthographic projection of the light-emitting structure of the light-emitting device on the array substrate is a fourth projection pattern; among the first light-emitting devices, the second light-emitting devices, and the third light-emitting devices, an angle between a longest straight side of the fourth projection pattern of at least one type of light-emitting device and the arrangement direction of the plurality of scan lines is configured to be the preset angle;
in the fourth projection pattern of the at least one type of light-emitting device, a ratio of the longest straight side of the fourth projection pattern to a length of the fourth projection pattern along a first direction ranges from 1.3 to 2, and the first direction intersects with an extension direction of the longest straight side of the fourth projection pattern;
in the fourth projection pattern of the at least one type of light-emitting device, the longest straight side of the fourth projection pattern is greater than 10 μm;
an area of the fourth projection pattern of the second light-emitting device is greater than an area of the fourth projection pattern of the first light-emitting device, and less than an area of the fourth projection pattern of the third light-emitting device; and
an angle between the longest straight side of the fourth projection pattern of the first light-emitting device and the arrangement direction of the plurality of scan lines is configured to be the preset angle, and an angle between the longest straight side of the fourth projection pattern of the second light-emitting device and the arrangement direction of the plurality of scan lines is configured to be the preset angle; or for each light-emitting device among the first light-emitting devices, the second light-emitting devices, and the third light-emitting devices, the angle between the longest straight side of the fourth projection pattern of each light-emitting device and the arrangement direction of the plurality of scan lines is configured to be the preset angle.

28. The display panel according to claim 1, further comprising a plurality of encapsulation portions, wherein the plurality of encapsulation portions comprise a plurality of first encapsulation portions corresponding to the plurality of first light-emitting devices, a plurality of second encapsulation portions corresponding to the plurality of second light-emitting devices, and a plurality of third encapsulation portions corresponding to the plurality of third light-emitting devices, the plurality of first encapsulation portions are disposed on a side, facing away from the array substrate, of the corresponding first light-emitting devices, the plurality of second encapsulation portions are disposed on a side, facing away from the array substrate, of the corresponding second light-emitting devices, and the plurality of third encapsulation portions are disposed on a side, facing away from the array substrate, of the corresponding third light-emitting devices;
an orthographic projection of an encapsulation portion on the array substrate is a fifth projection pattern; among the first encapsulation portions, the second encapsulation portions, and the third encapsulation portions, an angle between a longest straight side of the fifth projection pattern of at least one type of encapsulation portion and the arrangement direction of the plurality of scan lines is configured to be the preset angle;
in the fifth projection pattern of the at least one type of encapsulation portion, a ratio of the longest straight side of the fifth projection pattern to a length of the fifth projection pattern along a first direction ranges from 1.3 to 2; and the first direction intersects an extension direction of the longest straight side of the fifth projection pattern;
in the fifth projection pattern of the at least one type of encapsulation portion, the longest straight side of the fifth projection pattern is greater than 10 μm;
an area of the fifth projection pattern of the second encapsulation portion is greater than an area of the fifth projection pattern of the first encapsulation portion, and less than an area of the fifth projection pattern of the third encapsulation portion; and
an angle between the longest straight side of the fifth projection pattern of the first encapsulation portion and the arrangement direction of the plurality of scan lines is configured to be the preset angle, and an angle between the longest straight side of the fifth projection pattern of the second encapsulation portion and the arrangement direction of the plurality of scan lines is configured to be the preset angle; or for each encapsulation portion among the first encapsulation portions, the second encapsulation portions, and the third encapsulation portions, the angle between the longest straight side of the fifth projection pattern of each encapsulation portion and the arrangement direction of the plurality of scan lines is configured to be the preset angle.

29. A display panel, comprising:
an array substrate, comprising a plurality of scan lines arranged at intervals;
an isolation structure, located on a side of the array substrate and defining a plurality of isolation openings, the plurality of isolation openings comprising a plurality of first isolation openings, a plurality of second isolation openings, and a plurality of third isolation openings;
a plurality of light-emitting devices, located on the side of the array substrate and comprising a plurality of first light-emitting devices, a plurality of second light-emitting devices, and a plurality of third light-emitting devices;
wherein the plurality of first light-emitting devices are disposed corresponding to the plurality of first isolation openings, the plurality of second light-emitting devices are disposed corresponding to the plurality of second isolation openings, and the plurality of third light-emitting devices are disposed corresponding to the plurality of third isolation openings; each of the plurality of light-emitting devices comprises a first electrode, a light-emitting structure, and a second electrode stacked in sequence, and the second electrode is electrically connected to the isolation structure; and
an orthographic projection of an end, close to the array substrate, of an isolation opening on the array substrate is a first projection pattern; among the first isolation openings, the second isolation openings, and the third isolation openings, a longest straight side of the first projection pattern of at least one type of isolated opening is greater than a length of the first projection pattern along a first direction; the first direction intersects with an extension direction of the longest straight side of the first projection pattern, and an orthographic projection of the second electrode of the light emitting device corresponding to the at least one isolation opening on the array substrate overlaps with the longest straight side of the first projection pattern.

30. A display device, comprising:
a display panel, wherein the display panel comprises:
an array substrate
an isolation structure, located on a side of the array substrate and defining a plurality of isolation openings, the plurality of isolation openings comprising a plurality of first isolation openings, a plurality of second isolation openings, and a plurality of third isolation openings;
a plurality of light-emitting devices, located on the side of the array substrate and comprising a plurality of first light-emitting devices, a plurality of second light-emitting devices, and a plurality of third light-emitting devices;
wherein the plurality of first light-emitting devices are disposed corresponding to the plurality of first isolation openings, the plurality of second light-emitting devices are disposed corresponding to the plurality of second isolation openings, the plurality of third light-emitting devices are disposed corresponding to the plurality of third isolation openings; the first light-emitting devices, second light-emitting devices, and third light-emitting devices are configured to emit light of different colors respectively; each of the plurality of light-emitting devices comprises a first electrode, a light-emitting structure, and a second electrode stacked in sequence, and the second electrode is electrically connected to the isolation structure; an orthographic projection of an end, close to the array substrate, of an isolation opening on the array substrate is a first projection pattern; and among the first isolation openings, the second isolation openings, and the third isolation openings, an orthographic projection of the second electrode of the light-emitting device corresponding to at least one type of isolation opening on the array substrate overlaps with a longest straight side of the first projection pattern of the at least one type of isolation opening; and
a plurality of connecting fingers arranged at intervals, wherein an arrangement direction of the plurality of connecting fingers intersects with the longest straight side of the first projection pattern of the at least one type of isolation opening.
